(19) United States
(12) Patent Application Publication
(10) Pub. No.: US 2025/0338633 A1
(43) Pub. Date: Oct. 30, 2025

(54) TIN OXIDE TRANSISTORS WITH TUNNELING CONTACT BARRIER LINERS AND METHODS FOR FORMING THE SAME

(71) Applicant: Taiwan Semiconductor Manufacturing Company Limited, Hsinchu (TW)

(72) Inventors: Gerben Doornbos, Kessel-Lo (BE); Ken-Ichi Goto, Hsinchu (TW); Georgios Vellianitis, Heverlee (BE); Viraj Nilesh Madhiwala, Kessel-Lo (BE)

(21) Appl. No.: 18/648,067

(22) Filed: Apr. 26, 2024

(51) Int. Cl. H01L 29/66; H01L 29/40; H01L 29/45; H01L 29/49; H01L 29/786

(52) U.S. Cl. CPC H10D 99/00; H10D 30/6739; H10D 30/6755; H10D 64/118; H10D 64/62

(57) ABSTRACT

Contacts that protect tin oxide semiconductor material in a thin-film transistor may be provided by forming a stack including a gate electrode, a gate dielectric, and an active layer comprising a tin oxide semiconductor material over a dielectric material layer that overlies a substrate; forming an assembly of a source electrode, a drain electrode, and an insulating layer extending between the source electrode and the drain electrode over the dielectric material layer prior to, or after, formation of the stack; and depositing a tunneling dielectric barrier liner on the stack or on the assembly. The tunneling dielectric barrier liner is in contact with the active layer, the source electrode, and the drain electrode after formation of the stack and the assembly.

### BACKGROUND

Only a few compound semiconductor oxides are practically usable for the purpose of forming thin-film transistor channels. One of such compound semiconductor oxides is tin oxide having a chemical composition of SnOₓ, in which the value of x is close to 1.0, which may be a p-type semiconductor. In order to properly function as a compound semiconductor material within a thin-film transistor, it is desirable to protect the SnOₓ from oxidation. It is also desirable to suppress the formation of surface states on the SnOₓ.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, first metal interconnect structures formed in lower-level dielectric material layers, an insulating material layer, and an optional etch stop dielectric layer according to an embodiment of the present disclosure.

FIGS. 2A-2C are various views (top and vertical cross sectional) of a region of the first exemplary structure after formation of a gate contact via structure according to an embodiment of the present disclosure. FIG. 2A is a top-down view, FIG. 2B is a vertical cross-sectional view along the vertical plane B-B′ of FIGS. 2A and 2C, and FIG. 2C is a vertical cross-sectional view along the vertical plane C-C′ of FIGS. 2A and 2B.

FIGS. 3A-3C are various views (top and vertical cross sectional) of a region of the first exemplary structure after formation of a gate electrode material layer, a gate dielectric material layer, and a semiconductor material layer according to an embodiment of the present disclosure. FIG. 3A is a top-down view, FIG. 3B is a vertical cross-sectional view along the vertical plane B-B′ of FIGS. 3A and 3C, and FIG. 3C is a vertical cross-sectional view along the vertical plane C-C′ of FIGS. 3A and 3B.

FIGS. 4A-4C are various views (top and vertical cross sectional) of a region of the first exemplary structure after formation of a layer stack including a gate electrode, a gate dielectric, and an active layer according to an embodiment of the present disclosure. FIG. 4A is a top-down view, FIG. 4B is a vertical cross-sectional view along the vertical plane B-B′ of FIGS. 4A and 4C, and FIG. 4C is a vertical cross-sectional view along the vertical plane C-C′ of FIGS. 4A and 4B.

FIGS. 5A-5C are various views (top and vertical cross sectional) of a region of the first exemplary structure after formation of an insulating layer according to an embodiment of the present disclosure. FIG. 5A is a top-down view, FIG. 5B is a vertical cross-sectional view along the vertical plane B-B′ of FIGS. 5A and 5C, and FIG. 5C is a vertical cross-sectional view along the vertical plane C-C′ of FIGS. 5A and 5B.

FIGS. 6A-6C are various views (top and vertical cross sectional) of a region of the first exemplary structure after formation of source/drain cavities according to an embodiment of the present disclosure. FIG. 6A is a top-down view, FIG. 6B is a vertical cross-sectional view along the vertical plane B-B′ of FIGS. 6A and 6C, and FIG. 6C is a vertical cross-sectional view along the vertical plane C-C′ of FIGS. 6A and 6B.

FIGS. 7A-7C are various views (top and vertical cross sectional) of a region of the first exemplary structure after depositing a tunneling dielectric barrier liner and at least one conductive material according to an embodiment of the present disclosure. FIG. 7A is a top-down view, FIG. 7B is a vertical cross-sectional view along the vertical plane B-B′ of FIGS. 7A and 7C, and FIG. 7C is a vertical cross-sectional view along the vertical plane C-C′ of FIGS. 7A and 7B. The tunneling dielectric barrier liner may act as diffusion barrier, and/or as tunneling dielectric. The tunneling dielectric barrier liner may reduce the penetration of a wave function from a metal into a semiconductor, preventing formation of metal induced gap states.

FIGS. 8A-8C are various views of a region of the first exemplary structure after formation of a source electrode and a drain electrode according to an embodiment of the present disclosure. FIG. 8A is a top-down view, FIG. 8B is a vertical cross-sectional view along the vertical plane B-B′ of FIGS. 8A and 8C, and FIG. 8C is a vertical cross-sectional view along the vertical plane C-C′ of FIGS. 8A and 8B.

FIGS. 9A-9C are various views of a region of a first alternative configuration of the first exemplary structure after formation of a source electrode and a drain electrode according to an embodiment of the present disclosure. FIG. 9A is a top-down view, FIG. 9B is a vertical cross-sectional view along the vertical plane B-B′ of FIGS. 9A and 9C, and FIG. 9C is a vertical cross-sectional view along the vertical plane C-C′ of FIGS. 9A and 9B.

FIGS. 10A-10C are various views of a region of a second alternative configuration of the first exemplary structure after formation of a source electrode and a drain electrode according to an embodiment of the present disclosure. FIG. 10A is a top-down view, FIG. 10B is a vertical cross-sectional view along the vertical plane B-B′ of FIGS. 10A and 10C, and FIG. 10C is a vertical cross-sectional view along the vertical plane C-C′ of FIGS. 10A and 10B.

FIGS. 11A-11C are various views of a region of a third alternative configuration of the first exemplary structure after formation of a top gate dielectric and a top gate electrode according to an embodiment of the present disclosure. FIG. 11A is a top-down view, FIG. 11B is a vertical cross-sectional view along the vertical plane B-B′ of FIGS. 11A and 11C, and FIG. 11C is a vertical cross-sectional view along the vertical plane C-C′ of FIGS. 11A and 11B.

FIGS. 12A-12C are various views of a region of the third alternative configuration of the first exemplary structure after formation of a source electrode and a drain electrode according to an embodiment of the present disclosure. FIG. 12A is a top-down view, FIG. 12B is a vertical cross-sectional view along the vertical plane B-B′ of FIGS. 12A and 12C, and FIG. 12C is a vertical cross-sectional view along the vertical plane C-C′ of FIGS. 12A and 12B.

FIGS. 13A-13C are various views of a region of a fourth alternative configuration of the first exemplary structure after formation of a source electrode and a drain electrode according to an embodiment of the present disclosure. FIG. 13A is a top-down view, FIG. 13B is a vertical cross-sectional view along the vertical plane B-B′ of FIGS. 13A and 13C, and FIG. 13C is a vertical cross-sectional view along the vertical plane C-C′ of FIGS. 13A and 13B.

FIGS. 14A-14C are various views of a region of a fifth alternative configuration of the first exemplary structure after formation of a source electrode and a drain electrode according to an embodiment of the present disclosure. FIG. 14A is a top-down view, FIG. 14B is a vertical cross-sectional view along the vertical plane B-B′ of FIGS. 14A and 14C, and FIG. 14C is a vertical cross-sectional view along the vertical plane C-C′ of FIGS. 14A and 14B.

FIG. 15 is a vertical cross-sectional view of a region of a second exemplary structure after formation a source electrode, an insulating layer, and a drain electrode according to an embodiment of the present disclosure.

FIG. 16 is a vertical cross-sectional view of a region of the second exemplary structure after formation a tunneling dielectric barrier liner, a semiconductor material layer, a gate dielectric layer, and a gate electrode material layer according to an embodiment of the present disclosure.

FIG. 17 is a vertical cross-sectional view of a region of the second exemplary structure after patterning the tunneling dielectric barrier liner, the semiconductor material layer, the gate dielectric layer, and the gate electrode material layer according to an embodiment of the present disclosure.

FIG. 18 is a vertical cross-sectional view of a region of the second exemplary structure after patterning the drain electrode according to an embodiment of the present disclosure.

FIGS. 19A and 19B are vertical cross-sectional views of a region of two configurations of the second exemplary structure after formation of a contact-level dielectric layer and contact via structures according to an embodiment of the present disclosure.

FIG. 20 is a vertical cross-sectional view of a region of a third exemplary structure after formation of a source electrode and a drain electrode in an insulating layer according to an embodiment of the present disclosure.

FIG. 21 is a vertical cross-sectional view of a region of the third exemplary structure after formation a tunneling dielectric barrier liner, a semiconductor material layer, a gate dielectric layer, and a gate electrode material layer according to an embodiment of the present disclosure.

FIG. 22 is a vertical cross-sectional view of a region of the third exemplary structure after patterning the tunneling dielectric barrier liner, the semiconductor material layer, the gate dielectric layer, and the gate electrode material layer according to an embodiment of the present disclosure.

FIGS. 23A and 23B are vertical cross-sectional views of a region of two configurations of the third exemplary structure after formation of a contact-level dielectric layer and contact via structures according to an embodiment of the present disclosure.

FIG. 24 is a vertical cross-sectional view of the first exemplary structure after formation of upper-level metal interconnect structures according to an embodiment of the present disclosure.

FIG. 25 is a vertical cross-sectional view of the second exemplary structure after formation of upper-level metal interconnect structures according to an embodiment of the present disclosure.

FIG. 26 is a vertical cross-sectional view of the third exemplary structure after formation of upper-level metal interconnect structures according to an embodiment of the present disclosure.

FIG. 27 is a schematic representation of a band structure in the vicinity of a tunneling dielectric barrier liner according to an aspect of the present disclosure.

FIG. 28 is a first flowchart that illustrates the general processing steps for manufacturing the semiconductor devices of the present disclosure.

FIG. 29 is a second flowchart that illustrates the general processing steps for manufacturing the semiconductor devices of the present disclosure.

FIG. 30 is a third flowchart that illustrates the general processing steps for manufacturing the semiconductor devices of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Oxide semiconductor materials are used for channel layers of thin-film transistors (TFTs) that are formed as back-end-of-line (BEOL) structures. Many n-type oxide semiconductor materials are known in the art, which include indium gallium zinc oxide, indium oxide, indium tin oxide, indium tungsten oxide, etc. However, there is a dearth of suitable p-type oxide semiconductor materials.

Tin oxide is one of the few compound semiconductor oxides that is practically usable for the purpose of forming thin-film transistor channels. The properties of tin oxide depend on the ratio between tin and oxygen. For instance, stoichiometric tin monoxide (SnO, or stannous oxide, or tin(II)oxide, where tin is in the +2 oxidation state, denoted by Sn²⁺) can be a p-type semiconductor where conduction is dominated by the flow of holes. A small (for instance less than 1 atomic percent) concentration of tin vacancies (i.e., missing tin atoms) may act as acceptor states and increase the density of positively charge holes. On the other hand, stoichiometric tin dioxide (SnO₂, or stannic oxide, or tin(IV)oxide, where tin is in the +4 oxidation state, denoted by Sn⁴⁺), can be an n-type semiconductor where conduction is dominated by the flow of electrons. A small (for instance less than 1 atomic percent) concentration of oxygen vacancies (i.e., missing oxygen atoms) may act as donor states and increase the concentration of negatively charged electrons. It is therefore desirable to control the exact ratio between tin and oxygen in a semiconductor process. For instance, if in an application tin monoxide is desired, the presence of tin dioxide must be avoided. This is hampered by the inherent fragility of tin monoxide. For example, exposure to an oxygen containing ambient may oxidize tin monoxide into tin dioxide, either partly or fully. Exposure to hydrogen may lead to oxygen vacancies in tin monoxide which may be undesired. Interaction with certain metals, for instance TiN or Al which are known oxygen scavengers, has a similar effect. Furthermore, the properties of tin monoxide depend on crystallinity. For instance, tin monoxide can form a tetragonal lattice, but can also appear in an amorphous phase. Reported hole mobilities depend strongly on the crystalline phase. It is therefore critical that both chemical composition, and crystallinity, of a tin monoxide compound semiconductor channel are well controlled.

Additionally, the interface between tin monoxide and a metal contact may pose a significant obstacle. The penetration of the metal wave function into tin monoxide may lead to the formation of metal-induced gap states (MIGS). The MIGS states are associated with a high Schottky barrier, which may severely degrade contact resistance, impeding the efficiency of charge carrier injection, and thus, the overall performance of the thin-film transistor.

There is a need for a processing scheme for integrating tin monoxide into a thin-film transistor in a manner that resolves the various issues discussed above. Embodiments of the present disclosure provide methods and structures for maintaining the desired characteristics of tin monoxide while enhancing tin monoxide's stability and interface quality with metal contacts in order to exploit the advantageous properties of tin monoxide. Specifically, embodiments of the present disclosure enhance the performance of tin monoxide transistors (e.g., thin-film transistors, TFTs) by incorporating a tunneling dielectric barrier liner. The material composition and thickness of the tunneling dielectric barrier liner may be selected to (i) eliminate or reduce formation of the MIGS, (ii) optimize electron tunneling between tin monoxide and a metal contact, and (iii) act as chemical diffusion barrier. The tunneling dielectric barrier liner may include alkaline-earth metal oxides, and may comprise a layer stack including magnesium oxide, strontium oxide, and calcium oxide. Alternatively or additionally, the tunneling dielectric barrier liner may comprise a material selected from dielectric oxides of light Group 13 elements or transition metal oxides with a band gap exceeding 3.0 eV. Alternatively or additionally, the tunneling dielectric barrier liner may comprise a material selected from oxygen-free nitrides of light Group 13 elements or silicon nitride in the liner.

The integration of the tunneling dielectric barrier liner not only mitigates the sensitivity of tin monoxide to environmental factors, but also ensures low contact resistance by preventing the penetration of metal wave functions into the tin monoxide layer for formation of the metal-induced gap states (MIGS). The prevention of formation of MIGS is pivotal for maintaining performance and reliability of the thin-film transistors. The thickness of the tunneling dielectric barrier liner is selected to balance effective protection from MIGS formation and efficient electron tunneling. Embodiments of the present disclosure may be used to provide high-performance tin monoxide thin-film transistors that may be used in BEOL semiconductor circuits.

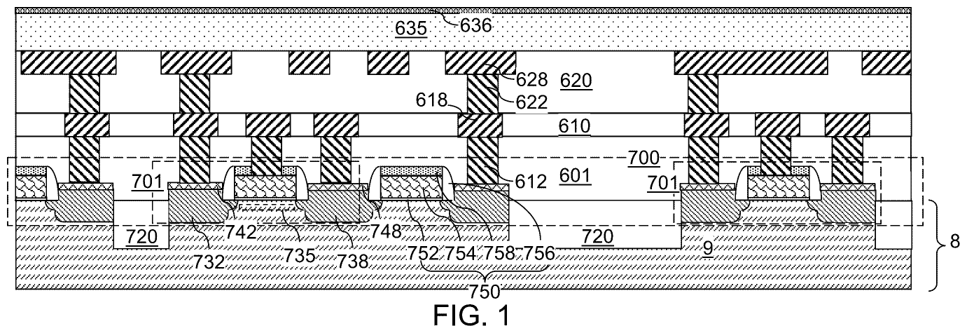

Referring to FIG. 1, a first exemplary structure according to an embodiment of the present disclosure is illustrated. The exemplary structure includes a substrate 8. Generally, the substrate 8 comprises, and/or consists essentially of, at least one material selected from an insulating material, a semiconductor material, and a metallic material. In one embodiment, the substrate 8 may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source region 732, a drain region 738, a semiconductor channel 735 that includes a surface portion of the substrate 8 extending between the source region 732 and the drain region 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738.

One or more of the field effect transistors 701 in a CMOS circuitry 700 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel.

In one embodiment, the substrate 8 may include a single crystalline silicon substrate, and the field effect transistors 701 may include a respective portion of the single crystalline silicon substrate as a semiconducting channel. As used herein, a “semiconducting” element may refer to an element having electrical conductivity in the range from 1.0×10⁻⁵ S/m to 1.0×10⁵ S/m. As used herein, a “semiconductor material” may refer to a material having electrical conductivity less than 1 S/m in the absence of electrical dopants therein, and is capable of producing a doped material having electrical conductivity in a range from 1.0 S/m to 1.0×10⁷ S/m upon suitable doping with an electrical dopant. As used herein, a dielectric material or an insulating material refers to a material having electrical conductivity less than 1.0×10⁻⁵ S/m. A conductive material refers to a material having electrical conductivity greater than 1.0×10⁵ S/m or otherwise expressly identified as a conductive material in this disclosure. All measurements are taken at the standard condition, i.e., at 0 degrees Celsius and at 1 atmospheric pressure.

Various metal interconnect structures formed within dielectric layers may be subsequently formed over the substrate 8 and the semiconductor devices thereupon (such as field effect transistors 701). In an illustrative example, the dielectric layers may include, for example, a contact-level dielectric layer 601 that may be a layer that surrounds the contact structure connected to the source and drains, a first interconnect-level dielectric layer 610, and a second interconnect-level dielectric layer 620. The metal interconnect structures may include device contact via structures 612 formed in the contact-level dielectric layer 601 and contact a respective component of the CMOS circuitry 700, first metal line structures 618 formed in the first interconnect-level dielectric layer 610, first metal via structures 622 formed in a lower portion of the second interconnect-level dielectric layer 620, and second metal line structures 628 formed in an upper portion of the second interconnect-level dielectric layer 620.

Each of the dielectric material layers (601, 610, 620) may include a dielectric material such as undoped silicate glass, a doped silicate glass, organosilicate glass, amorphous fluorinated carbon, porous variants thereof, or combinations thereof. Each of the metal interconnect structures (612, 618, 622, 628) may include at least one conductive material, which may be a combination of a metallic barrier liner (such as a metallic nitride or a metallic carbide) and a metallic fill material. Each metallic barrier liner may include TIN, TaN, WN, TiC, TaC, and WC, and each metallic fill material portion may include W, Cu, Al, Co, Ru, Mo, Ta, Ti, alloys thereof, and/or combinations thereof. Other suitable metallic barrier liner and metallic fill materials within the contemplated scope of disclosure may also be used. In one embodiment, the first metal via structures 622 and the second metal line structures 628 may be formed as integrated line and via structures by a dual damascene process. The dielectric material layers (601, 610, 620) may also be referred to as lower-level dielectric material layers (601, 610, 620). The metal interconnect structures (612, 618, 622, 628) formed within in the lower-level dielectric material layers (601, 610, 620) are herein referred to as lower-level metal interconnect structures (612, 618, 622, 628).

In one embodiment, the substrate 8 may include a single crystalline silicon substrate, and lower-level dielectric material layers (601, 610, 620) embedding lower-level metal interconnect structures (612, 618, 622, 628) may be located above the single crystalline silicon substrate. Field effect transistors 701 including a respective portion of the single crystalline silicon substrate as a channel may be embedded within the lower-level dielectric material layers (601, 610, 620). The field effect transistors may be subsequently electrically connected to at least one of a gate electrode, a source electrode, and a drain electrode of one or more, or each, of thin-film transistors to be subsequently formed.

While the present disclosure is described using an embodiment in which a semiconductor substrate is used as the substrate 8, embodiments are expressly contemplated herein in which an insulating substrate or a conductive substrate is used as the substrate 8.

Transistors, for example, thin-film transistors, are formed in subsequent processing steps. The set of all dielectric layers that are formed prior to formation of the transistors (e.g., thin-film transistors or TFTs) is collectively referred to as lower-level dielectric material layers (601, 610, 620). The set of all metal interconnect structures that is formed within the lower-level dielectric material layers (601, 610, 620) is herein referred to as lower-level metal interconnect structures (612, 618, 622, 628). Generally, the lower-level metal interconnect structures (612, 618, 622, 628) are formed over the semiconductor material layer 9 in the substrate 8, and are embedded in the lower-level dielectric material layers (601, 610, 620).

In one embodiment, a planar dielectric layer having a uniform thickness may be formed over the lower-level dielectric material layers (601, 610, 620). The planar dielectric layer is herein referred to as an insulating material layer 635. The insulating material layer 635 includes a dielectric material such as undoped silicate glass, a doped silicate glass, organosilicate glass, or a porous dielectric material, and may be deposited by chemical vapor deposition. The thickness of the insulating material layer 635 may be in a range from 30 nm to 300 nm, although lesser and greater thicknesses may also be used.

An etch stop dielectric layer 636 may be optionally formed over the insulating material layer 635. The etch stop dielectric layer 636 includes an etch stop dielectric material providing higher etch resistance to an etch chemistry during a subsequently anisotropic etch process that etches a dielectric material to be subsequently deposited over the etch stop dielectric layer 636. For example, the etch stop dielectric layer 636 may include silicon carbide nitride, silicon nitride, silicon oxynitride, or a dielectric metal oxide such as aluminum oxide. The thickness of the etch stop dielectric layer 636 may be in a range from 3 nm to 40 nm, such as from 4 nm to 30 nm, although lesser and greater thicknesses may also be used.

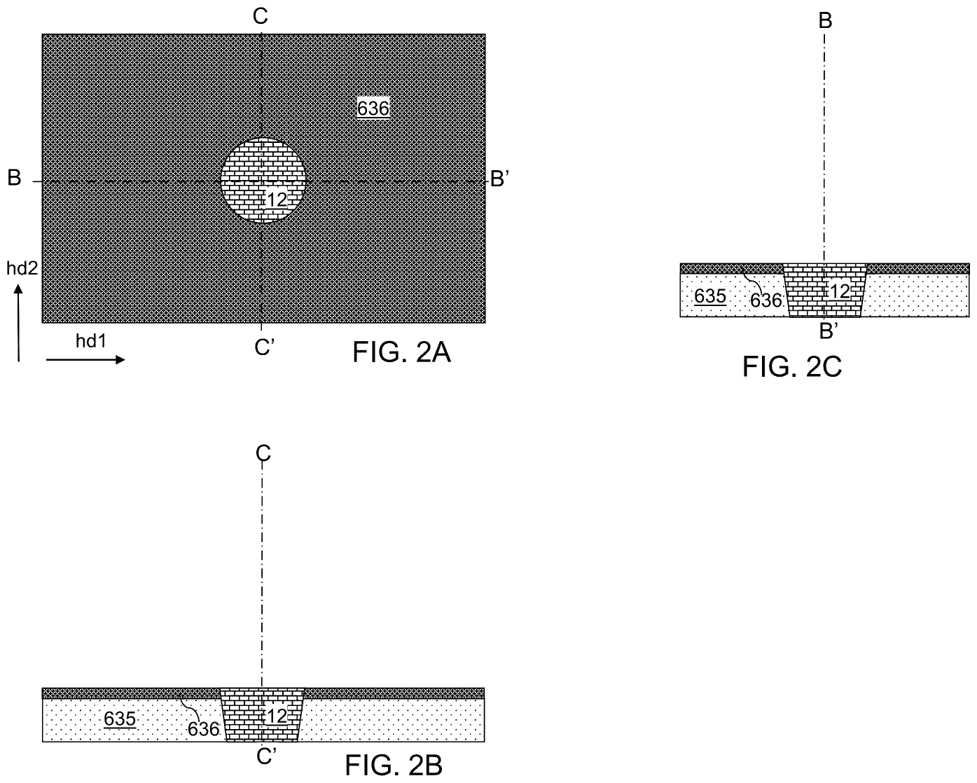

Referring to FIGS. 2A-2C, a region of the first exemplary structure for forming a transistor (e.g., thin-film transistor or TFT) is illustrated after formation of a gate contact via structure 12. For example, a via cavity may be formed through the optional etch stop dielectric layer 636 and the insulating material layer 635 on a respective one of the underlying metal interconnect structures (such as a second metal line structure 628 shown in FIG. 1), and at least one metallic material may be deposited in the via cavity. Excess portions of the at least one metallic material may be removed from above the horizontal plane including the top surface of the etch stop dielectric layer 636 by a planarization process such as a chemical mechanical polishing (CMP) process. A remaining portion of the at least one metallic material constitutes the gate contact via structure 12.

In one embodiment, multiple transistors (e.g., thin-film transistors or TFTs) may be formed over the lower-level dielectric material layers (601, 610, 620). In this embodiment, a two-dimensional array of gate contact via structures 12 may be formed through the etch stop dielectric layer 636 and the insulating material layer 635. In one embodiment, the two-dimensional array of gate contact via structures 12 may be repeated along a first horizontal direction hd1 with a first periodicity, and may be repeated along a second horizontal direction hd2 with the second periodicity. In one embodiment, the second horizontal direction hd2 may be perpendicular to the first horizontal direction hd1.

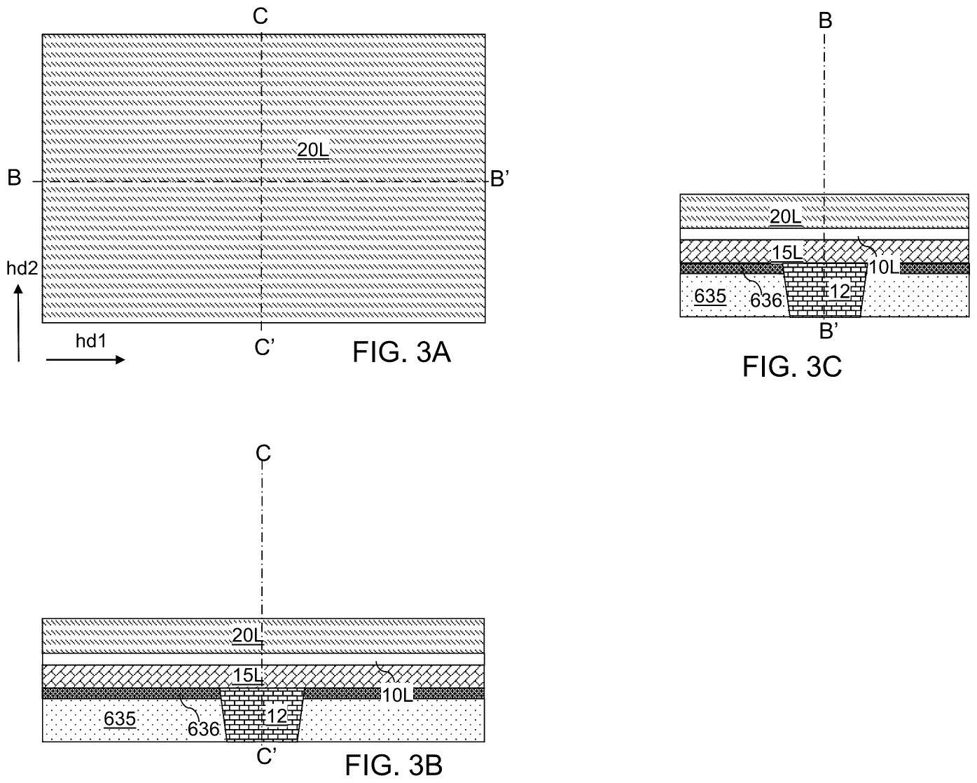

Referring to FIGS. 3A-3C, a gate electrode material layer 15L, a gate dielectric material layer 10L, and a semiconductor material layer 20L may be sequentially deposited over the etch stop dielectric layer 636.

The gate electrode material layer 15L comprises at least one conductive gate electrode material. The at least one conductive gate electrode material may include, for example, a metallic barrier liner material (such as TiN, TaN, and/or WN), a metallic fill material (such as Cu, W, Mo, Co, Ru, etc.). Other suitable metallic barrier liner and metallic fill materials are within the contemplated scope of disclosure. The gate electrode material layer 15L may be deposited by chemical vapor deposition (CVD), atomic layer deposition (ALD), or physical vapor deposition (PVD). The thickness of the gate electrode material layer 15L may be in a range from 20 nm to 200 nm, although lesser and greater thicknesses may also be used.

The gate dielectric material layer 10L may be formed over the gate electrode material layer 15L. The gate dielectric material layer 10L may include, but is not limited to, silicon oxide, silicon oxynitride, silicon nitride, a dielectric metal oxide (such as aluminum oxide, hafnium oxide, yttrium oxide, zirconium oxide, lanthanum oxide, etc.), or a stack thereof. Other suitable dielectric materials are within the contemplated scope of disclosure. In a non-limiting illustrative example, the gate dielectric material layer 10L may comprise, and/or may consist essentially of at least one dielectric metal oxide material (such as aluminum oxide, hafnium oxide, titanium oxide, tantalum oxide, lanthanum oxide, hafnium silicate, etc.), silicon oxide, silicon nitride, an ONO stack, or other gate dielectric material known in the art. The gate dielectric material layer 10L may be deposited by atomic layer deposition (ALD) or chemical vapor deposition (CVD). The thickness of the gate dielectric material layer 10L may be in a range from 1 nm to 20 nm, such as from 3 nm to 6 nm, although lesser and greater thicknesses may also be used.

According to an aspect of the present disclosure, the semiconductor material layer 20L comprises, and/or consists essentially of, tin oxide. The semiconductor material layer 20L may be deposited by physical vapor deposition (PVD), or atomic layer deposition (ALD), although other suitable deposition processes may be used. The thickness of the semiconductor material layer 20L may be in a range from 2 nm to 50 nm, such as from 3 nm to 30 nm and/or from 4 nm to 15 nm, although lesser and greater thicknesses may also be used.

Tin monoxide (SnO) is a compound semiconductor material that may exhibit p-type conductivity under suitable conditions. P-type conductivity means that the primary charge carriers in the material are “holes,” which are essentially places where an electron is absent, allowing for the movement of positive charge. The stoichiometry, or the ratio of oxygen to tin, plays a crucial role in determining the properties of tin oxide as a p-type semiconductor. The ideal stoichiometry of tin oxide for p-type conductivity is a 1:1 ratio of oxygen to tin, which corresponds to the stoichiometric compound of tin monoxide (SnO). In this stoichiometric form, SnO may have a tetragonal crystal structure. Crystalline SnO may be single crystalline or poly crystalline. SnO may also be amorphous. SnO may also be partly crystalline and partly amorphous. Small changes in stoichiometry may induce excess holes, for instance by forming tin vacancies. SnO may also be chemically doped with impurities, for instance La, Al, N, Na, K, Ni, to induce access holes.

However, maintaining this exact ratio is challenging due to the tendency of tin monoxide to oxidize further to tin dioxide (SnO₂), especially in the presence of oxygen at elevated temperatures, for instance in a semiconductor process. Tin dioxide (SnO₂) is more chemically stable than tin monoxide (SnO), and may exhibit n-type conductivity which may not be desired. Therefore, if tin monoxide is desired, the formation of tin dioxide must be avoided. Optical properties may also depend on the oxygen to tin ratio. For instance, the direct band gap of SnO is around 2.7 eV, and the direct band gap of SnO₂ is about 3.6 eV. Thus, SnO may absorb light in the visible range and may be useful for optoelectronic applications. SnO₂ is transparent to visible light.

As for crystallographic properties, stoichiometric SnO may have a tetragonal crystal structure, or may be amorphous, or may be partly crystalline and partly amorphous. Deviations from the stoichiometry may lead to undesired changes in the properties, for instance the hole mobility. Generally, SnO is chemically less stable than SnO₂, and is prone to further oxidation, which may deteriorate its characteristics. Protective layers or controlled atmospheres are often needed to maintain the desired tin monoxide phase. To maintain SnO in the desire phase, precise control of the fabrication environment is necessary. Inert ambient or low oxygen pressure in combination with temperature control may be necessary to prevent further oxidation of SnO after formation.

The electrical properties of a tin oxide material are dependent upon the atomic ratio of oxygen to tin (O:Sn) in the tin oxide material. For a p-type tin oxide semiconductor material, the values for O:Sn may be in a range from 0.95 to 1.15. In instances in which the O:Sn is in this range, tin vacancies create holes which act as charge carriers, leading to p-type conductivity. Lower values below 0.95 for O:Sn result in metallic tin formation. Higher values above 1.15 results in transition to an n-type tin oxide material due to formation of tin dioxide.

Generally, the electrical conductivity of stoichiometric tin monoxide (SnO) without any external doping may be in the range from 10⁻³ S/m to 0.1 S/m, although lower and higher electrical conductivities may also be realized by tuning deposition conditions. The electrical conductivity of stoichiometric tin dioxide (SnO₂) without any external doping may be in the range from 1.0 S/m to 100 S/m, although lower and higher electrical conductivities may also be realized by tuning deposition conditions. Suitable electrical doping may increase the electrical conductivity of stoichiometric tin monoxide, stoichiometric tin dioxide, and any non-stoichiometric tin oxide material.

For the purpose of embodiments of the present disclosure, the semiconductor material layer 20L comprises, and/or consists essentially of, a tin oxide material having an atomic oxygen to tin ratio in a range from 0.95 to 1.15, and preferably from 0.98 to 1.10. In this composition range, the tin oxide material in the semiconductor material layer may be semiconducting, and may have p-type conductivity. Tin vacancies (missing tin atoms) may generate holes which are the majority carriers for p-type conductivity.

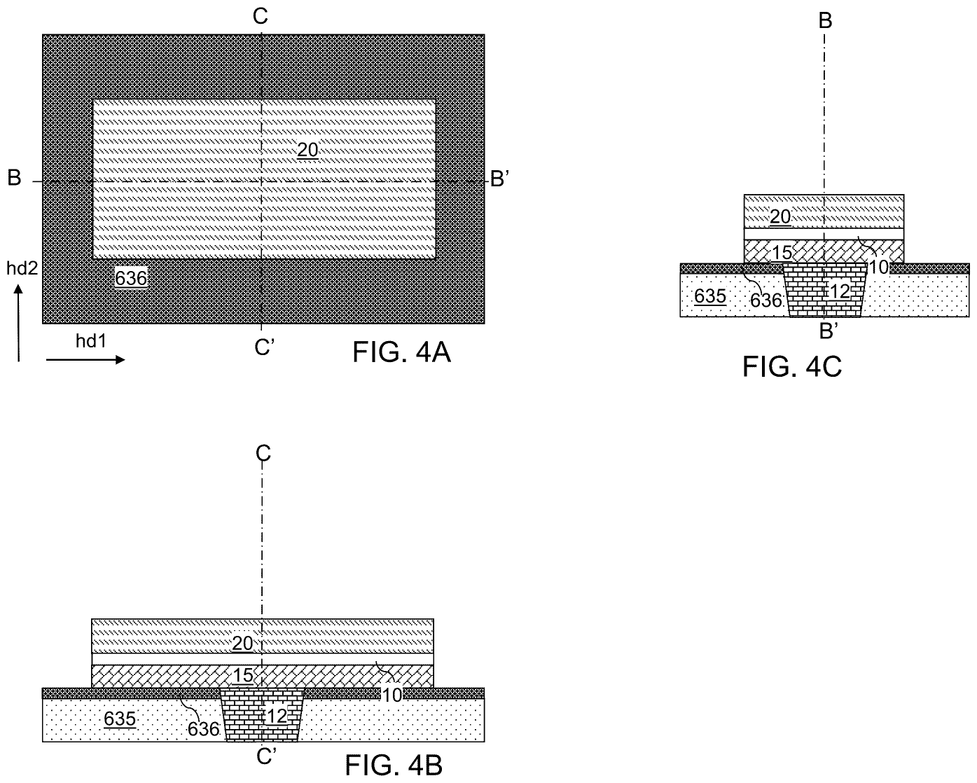

Referring to FIGS. 4A-4C, a photoresist layer (not shown) may be applied over the semiconductor material layer 20L, and may be lithographically patterned to form at least one discrete photoresist material portion, such as a two-dimensional array of discrete photoresist material portions. An anisotropic etch process may be performed to etch unmasked portions of the semiconductor material layer 20L, the gate dielectric material layer 10L, and the gate electrode material layer 15L. Each patterned portion of the semiconductor material layer 20L comprises an active layer 20, which is an active layer including a semiconducting oxide. Each patterned portion of the gate dielectric material layer 10L comprises a gate dielectric 10. Each patterned portion of the gate electrode material layer 15L comprise a gate electrode 15.

Each vertical stack of a gate electrode 15, a gate dielectric 10, and an active layer 20 may have vertically coincident sidewalls, i.e., sidewalls that are located within a same vertical plane. Each stack of a gate electrode 15 and a gate dielectric 10 is herein referred to as a gate stack (15, 10). The photoresist layer may be subsequently removed, for example, by ashing or dissolved by solution. In one embodiment, each layer within a vertical stack of a gate electrode 15, a gate dielectric 10, and an active layer 20 may have a same area in a plan view (such as a see-through top-down view) along a vertical direction that is perpendicular to the interface between the active layer 20 and the gate dielectric 10. In one embodiment, the gate electrode 15 laterally extends horizontally with a uniform gate electrode thickness, and has a same area as the active layer 20 and the gate dielectric 10. Generally, a stack (20, 10, 15) including a gate electrode 15, a gate dielectric 10, and an active layer 20 comprising a tin oxide compound semiconductor material composed primarily of tin monoxide may be formed over a dielectric material layer (601, 610, 620) which overlies a substrate 8. As used herein, tin oxide is composed primarily of tin monoxide if more than 50% of the tin atoms are in the +2 oxidation state. In general, the fraction of tin monoxide in a tin oxide layer can be expressed as the fraction of tin atoms being in the +2 oxidation state. The active layer 20 may comprise tin monoxide at a percentage in a range from 80% to 100%, such as from 95% to 100%, and/or from 99% to 100%, and/or from 99.8% to 100%. In case less than 100% of the active layer 20 is tin monoxide, the balance of the active layer 20 may be tin dioxide. In one embodiment, the tin oxide compound semiconductor material composed primarily of tin monoxide may be a p-type tin oxide semiconductor material.

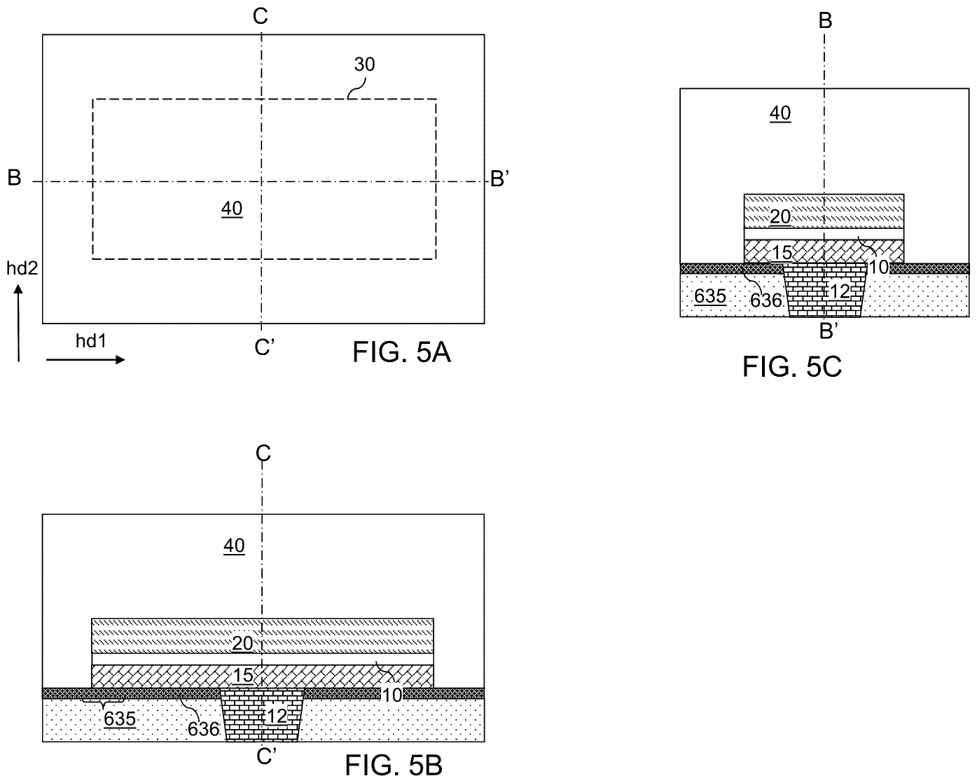

Referring to FIGS. 5A-5C, an insulating material such as undoped silicate glass, a doped silicate glass, or organosilicate glass may be deposited over each stack of a gate electrode 15, a gate dielectric 10, and an active layer 20 to form an insulating layer 40. The insulating layer 40 may be deposited by a self-planarizing deposition method (such as spin-on coating) or may be planarized after deposition (for example, by performing a chemical mechanical polishing process). The vertical distance between the top surface of each active layer 20 and the top surface of the insulating layer 40 may be in a range from 20 nm to 200 nm, although lesser and greater thicknesses may also be used.

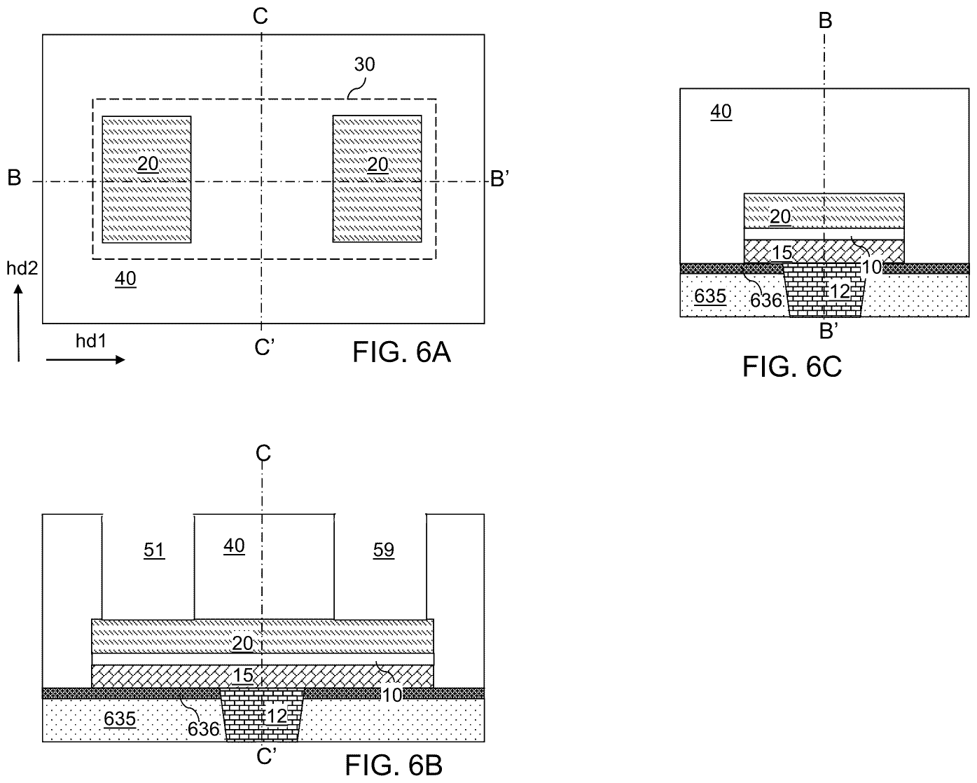

Referring to FIGS. 6A-6C, a photoresist layer (not shown) may be applied over the insulating layer 40, and may be lithographically patterned to form discrete openings therein. The pattern of the discrete openings in the photoresist layer may be transferred through the insulating layer 40 by an anisotropic etch process to form a source cavity 51 and a drain cavity 59 over each active layer 20.

According to an aspect of the present disclosure, the anisotropic etch process may have an etch chemistry that etches the materials of the insulating layer 40 selective to the material of the active layer 20. In other words, the anisotropic etch process may etch the materials of the insulating layer 40 without etching the material of the active layer 20. In this embodiment, the active layer 20 functions as an etch stop layer for the anisotropic etch process. Horizontal surface segments of the top surface of the active layer 20 may be physically exposed at the bottom of the source cavity 51 and at the bottom of the drain cavity 59. The physically exposed horizontal surface segments of the top surface of the active layer 20 may be coplanar with the interface between the top surface of the active layer 20 and the insulating layer 40.

The lateral spacing between the bottom periphery of the source cavity 51 and the bottom periphery of the drain cavity 59 defines the channel length of the transistor (e.g., TFT) to be subsequently formed. The channel length may be in a range from 10 nm to 500 nm, such as from 14 nm to 100 nm, although lesser and greater channel lengths may also be used.

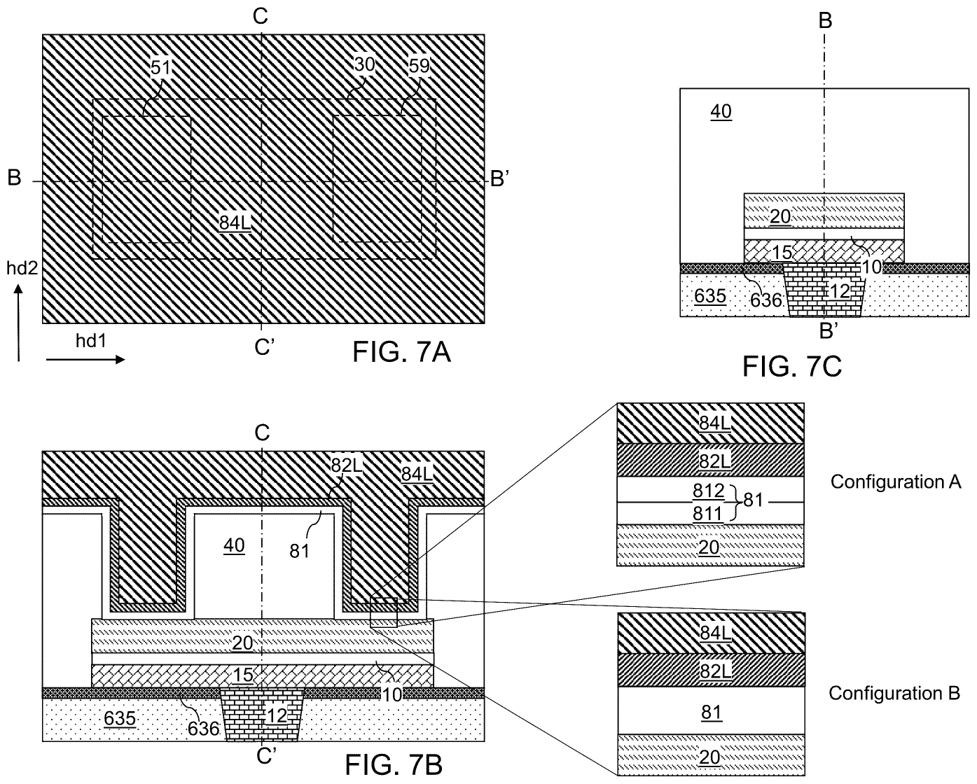

Referring to FIGS. 7A-7C, a tunneling dielectric barrier liner 81 may be deposited on the physically exposed surface segments of the active layer 20, on all sidewalls of the source cavity 51 and the drain cavity 59, and over the insulating layer 40. As used herein, a “tunneling dielectric barrier liner” refers to a dielectric liner that is configured to enable the tunneling of electrical currents therethrough. The electrical current through a tunneling dielectric barrier liner depends on the quantum mechanical probability of electrons “tunneling” through the tunneling dielectric barrier liner, which depends nonlinearly on the thickness of the tunneling dielectric barrier liner. The layer thickness of the tunneling dielectric barrier liner is chosen such that the barrier is practically transparent to the electrons, so that the tunneling dielectric barrier liner does not add to a contact resistance between a contact metal and a channel, and ohmic contacts are enabled. The tunneling dielectric barrier liner 81 is deposited in peripheral regions of the source cavity 51 and the drain cavity 59. Horizontal bottom surfaces of the tunneling dielectric barrier liner 81 contact horizontal surface segments of the top surface of the active layer 20 upon deposition of the tunneling dielectric barrier liner 81. The tunneling dielectric barrier liner 81 may be deposited by at least one conformal deposition process such as at least one atomic layer deposition (ALD) process, in which a thickness of horizontal segments of tunneling dielectric barrier liner 81 is nominally equal to a thickness of vertical segments of tunneling dielectric barrier liner 81. The tunneling dielectric barrier liner 81 may also be deposited by at least one nonconformal deposition process such as at least one physical vapor deposition (PVD) process, in which a thickness of horizontal segments of tunneling dielectric barrier liner 81 is nominally larger than a thickness of vertical segments of tunneling dielectric barrier liner 81. In embodiments in which the tunneling dielectric barrier liner 81 consists of a single material, one deposition process may be used to form the tunneling dielectric barrier liner 81. In embodiments in which the tunneling dielectric barrier liner 81 comprises two or more component layers having different material compositions, two or more deposition processes may be used to form the tunneling dielectric barrier liner 81.

According to an aspect of the present disclosure, the tunneling dielectric barrier liner 81 comprises a dielectric material that may provide tunneling of charge carriers (such as electrons) therethrough, while blocking diffusion of oxygen atoms, hydrogen atoms, and metals therethrough. Further, the dielectric material of the tunneling dielectric barrier liner 81 comprises a material that reduces formation of metal-induced gap states, which are surface electronic states that function as charge traps and increases contact resistance across the semiconductor material (i.e., p-type tin oxide) of the active layer 20 and a metallic contact structure (such as a source electrode or a drain electrode) to be subsequently formed. To enable charge tunneling, the thickness of the tunneling dielectric barrier liner 81 is in a range from 0.4 nm to 4 nm, and preferably from 0.5 nm to 2 nm, and more preferably from 0.6 nm to 1.2 nm.

According to an embodiment of the present disclosure, the tunneling dielectric barrier liner 81 comprises at least one material selected from alkaline-earth metal oxides. Exemplary alkaline-earth metal oxides include MgO, CaO, and SrO. In one embodiment, the tunneling dielectric barrier liner 81 comprises a layer stack including at least two alkaline-earth metal oxide layers (811, 812). For example, the at least two alkaline-earth metal oxide layers (811, 812) may comprise a first alkaline-earth metal oxide layer 811 and a second alkaline-earth metal oxide layer 812 as illustrated in the inset labeled as “Configuration A.” Optionally, the tunneling dielectric barrier liner 81 may further comprise a third alkaline-earth metal oxide layer (not shown) that is formed on the second alkaline-earth metal oxide layer. In one embodiment, the tunneling dielectric barrier liner 81 comprises a layer stack including a magnesium oxide layer and a calcium oxide layer. In this embodiment, the magnesium oxide layer may be deposited directly on the active layer 20, or the calcium oxide layer may be deposited directly on the active layer 20.

In one embodiment, the tunneling dielectric barrier liner 81 comprises a layer stack including two magnesium oxide layers spaced by a calcium oxide layer. In one embodiment, the tunneling dielectric barrier liner 81 comprises a layer stack including two calcium oxide layers spaced by a magnesium oxide layer. In one embodiment, the tunneling dielectric barrier liner 81 comprises a layer stack including a magnesium oxide layers, a calcium oxide layer, and a strontium oxide layer in any order. In one embodiment, the tunneling dielectric barrier liner 81 comprises a layer stack including two magnesium oxide layers spaced by a strontium oxide layer. In one embodiment, the tunneling dielectric barrier liner 81 comprises a layer stack including two calcium oxide layers spaced by a strontium oxide layer.

In one embodiment, the tunneling dielectric barrier liner 81 may consist of a single alkaline-earth metal oxide layer as illustrated in the inset labeled as “Configuration B.” The single alkaline-earth metal oxide layer may be a magnesium oxide layer, a calcium oxide layer, or a strontium oxide layer.

In one embodiment, the tunneling dielectric barrier liner 81 comprises a dielectric oxide of a light Group 13 element or a transition metal oxide having a band gap larger than 3.0 eV. As used herein, a light Group 13 element refers to B, Al, and Ga. Aluminum oxide (Al₂O₃) has a band gap of 8.8 eV, and gallium oxide (Ga₂O₃) has a band gap of 4.8 eV. Transition metal oxides having a band gap greater than 3.0 eV include, for example, zinc oxide having a band gap of about 3.37 eV, titanium dioxide (TiO₂) having a band gap of 3.0-3.2 eV, zirconium dioxide (ZrO₂) having a band gap of 5.3-5.7 eV, and hafnium dioxide (HfO₂) having a band gap of about 5.7 eV. As discussed above, p-doped tin oxide has a direct band gap of about 2.7 eV. Use of a dielectric oxide of a light Group 13 element or a transition metal oxide having a band gap larger than 3.0 eV ensures that penetration of metal-induced gap states through the tunneling dielectric barrier liner 81 is eliminated or minimized, and the contact resistance is not affected by metal-induced gap states. In one embodiment, a dielectric oxide having a band gap greater than 4.0 eV, or more preferably greater than 5.0 eV, may be used to suppress formation of metal-induced gap states.

In one embodiment, the tunneling dielectric barrier liner 81 comprises an oxygen-free nitride of a light Group 13 element or silicon nitride. Boron nitride has a band gap of 6.0 eV; aluminum nitride has a band gap of 6.2 eV, gallium nitride has a band gap of 3.4 eV, and silicon nitride has a band gap of 5.6 eV. Use of an oxygen-free nitride of a light Group 13 element or silicon nitride ensures that penetration of metal-induced gap states through the tunneling dielectric barrier liner 81 is eliminated or minimized, and the contact resistance is not affected by metal-induced gap states. In one embodiment, a dielectric nitride having a band gap greater than 5.0 eV, or more preferably greater than 6.0 eV, may be used to suppress formation of metal-induced gap states.

In one embodiment, the tunneling dielectric barrier liner 81 may comprise a layer stack of a first component layer including a dielectric oxide of a light Group 13 element or a transition metal oxide, and a second component layer including an oxygen-free nitride of a light Group 13 element or silicon nitride. The active layer 20 may contact the first component layer or the second component layer.

At least one conductive material may be deposited in the source cavity 51 and drain cavity 59 and over the insulating layer 40. The at least one conductive material may optionally include a metallic barrier liner layer 82L including metallic barrier liner material, and includes a metallic fill material layer 84L including a metallic fill material. The metallic barrier liner material, if used, may include a conductive metallic nitride or a conductive metallic carbide such as TIN, TaN, WN, TiC, TaC, and/or WC. The metallic fill material may include W, Cu, Al, Co, Ru, Mo, Ta, Ti, alloys thereof, and/or combinations thereof. Other suitable metallic barrier liner and metallic fill materials within the contemplated scope of disclosure may also be used. While the present disclosure is described using an embodiment in which the metallic barrier liner layer 82L is used, embodiments are expressly contemplated herein in which the metallic barrier liner layer 82L is omitted.

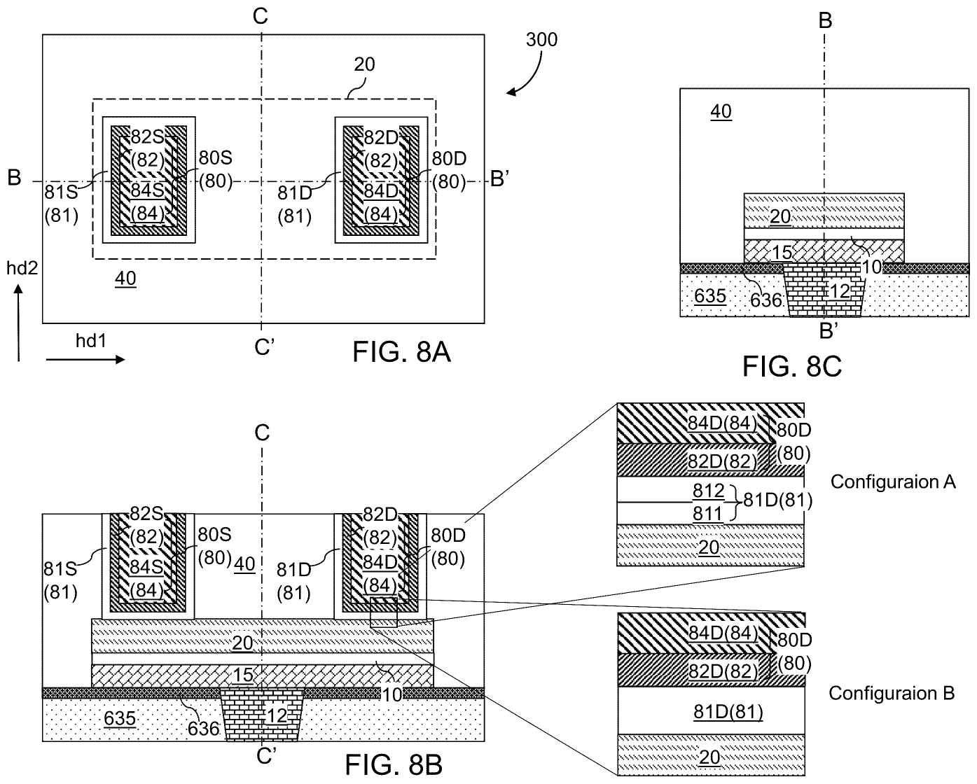

Referring to FIGS. 8A-8C, excess portions of the at least one conductive material may be removed from above the horizontal plane including the top surface of the insulating layer 40 by a planarization process, which may use a chemical mechanical polishing (CMP) process and/or a recess etch process. Other suitable planarization processes may be used. Each remaining portion of the at least one conductive material filling a source cavity 51 constitutes a source electrode 80S. Each remaining portion of the at least one conductive material filling a drain cavity 59 constitutes a drain electrode 80D.

Portions of the tunneling dielectric barrier liner 81 that overlie the horizonal plane including the top surface of the insulating layer 40 may be removed during the planarization process. Each of the source cavity 51 and the drain cavity 59 is partly filled with a respective remaining portion of the tunneling dielectric barrier liner 81. Each tunneling dielectric barrier liner 81 located within a respective one of the source cavity 51 and the drain cavity 59 may have a respective horizontally-extending portion in contact with a top surface segment of the active layer 20, and a respective vertical portion in contact with a respective sidewall of the insulating layer 40. A pair of tunneling dielectric barrier liners 81 may be provided, which comprises a source-side tunneling dielectric barrier liner 81S and a drain-side tunneling dielectric barrier liner 81D.

In one embodiment, each source electrode 80S may include a source metallic barrier liner 82S that is a remaining portion of the metallic barrier liner material of the metallic barrier liner layer 82L, and a source metal portion 84S that is a remaining portion of the metallic fill material of the metallic fill material layer 84L. Each drain electrode 80D may include a drain metallic barrier liner 82D that is a remaining portion of the metallic barrier liner material of the metallic barrier liner layer 82L, and a drain metal portion 84D that is a remaining portion of the metallic fill material of the metallic fill material layer 84L. The source electrode 80S may be formed in the source cavity 51, and the drain electrode 80D may be in the drain cavity 59. The source electrode 80S and the drain electrode 80D may be formed on the horizontal surface segments of the top surface of the active layer 20, respectively. A thin-film transistor 300 is thus formed.

Generally, a source electrode 80S and a drain electrode 80D may be formed on the tunneling dielectric barrier liner 81. Each of the source electrode 80S and the drain electrode 80D is spaced from a respective surface segment of the active layer 20 by a respective portion of the tunneling dielectric barrier liner 81. Horizontal bottom surfaces of the tunneling dielectric barrier liner 81 contact segments of the top surface of the active layer 20 upon deposition of the tunneling dielectric barrier liner 81.

More generally, an assembly of a source electrode 80S, a drain electrode 80D, and an insulating layer 40 extending between the source electrode 80S and the drain electrode 80D may be formed over the dielectric material layer (601, 610, 620) prior to, or after, formation of a stack (20, 10, 15) including a gate electrode 15, a gate dielectric 10, and an active layer 20. A tunneling dielectric barrier liner 81 may be formed on the stack (20, 10, 15) or on the assembly such that the tunneling dielectric barrier liner 81 is in contact with the active layer 20, the source electrode 80S, and the drain electrode 80D after formation of the stack (20, 10, 15) and the assembly. Embodiments in which the assembly of a source electrode 80S, a drain electrode 80D, and an insulating layer 40 is formed prior to formation of the stack (20, 10, 15) are described in sections that follow description of embodiments in which the assembly of a source electrode 80S, a drain electrode 80D, and an insulating layer 40 is formed after formation of the stack (20, 10, 15)

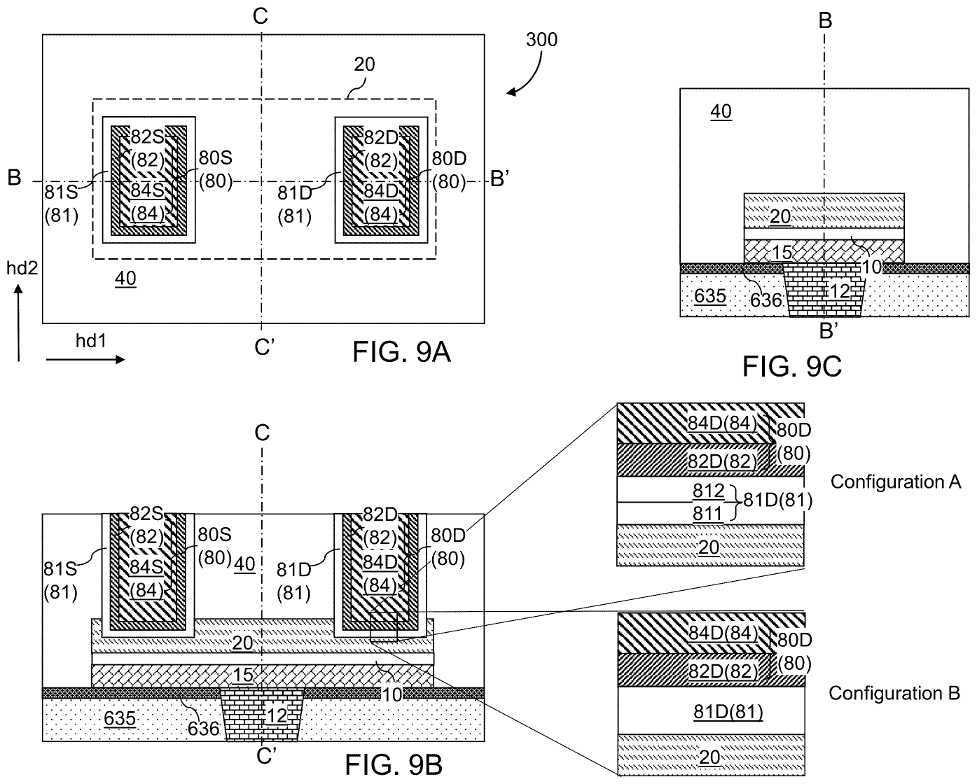

Referring to FIGS. 9A-9C, a first alternative configuration of the first exemplary structure is illustrated after formation of a source electrode 80S and a drain electrode 80D according to an embodiment of the present disclosure. The first alternative configuration of the first exemplary structure may be formed by extending the etch depth of the anisotropic etch process that forms the source cavity 51 and the drain cavity 59 at the processing steps of FIGS. 6A-6C such that bottom surfaces of the source cavity 51 and the drain cavity 59 are formed below the horizontal plane including the top surface of the active layer 20 and above the horizontal plane including the bottom surface of the active layer 20. In this embodiment, portions of the active layer 20 may be vertically recessed underneath the source cavity 51 and the drain cavity 59, and sidewalls of the tunneling dielectric barrier liner 81 may contact sidewalls of recessed portions of the active layer 20 upon deposition of the tunneling dielectric barrier liner 81. The bottom surface of each tunneling dielectric barrier liner 81 may contact a respective recessed horizontal surface segment of the active layer 20.

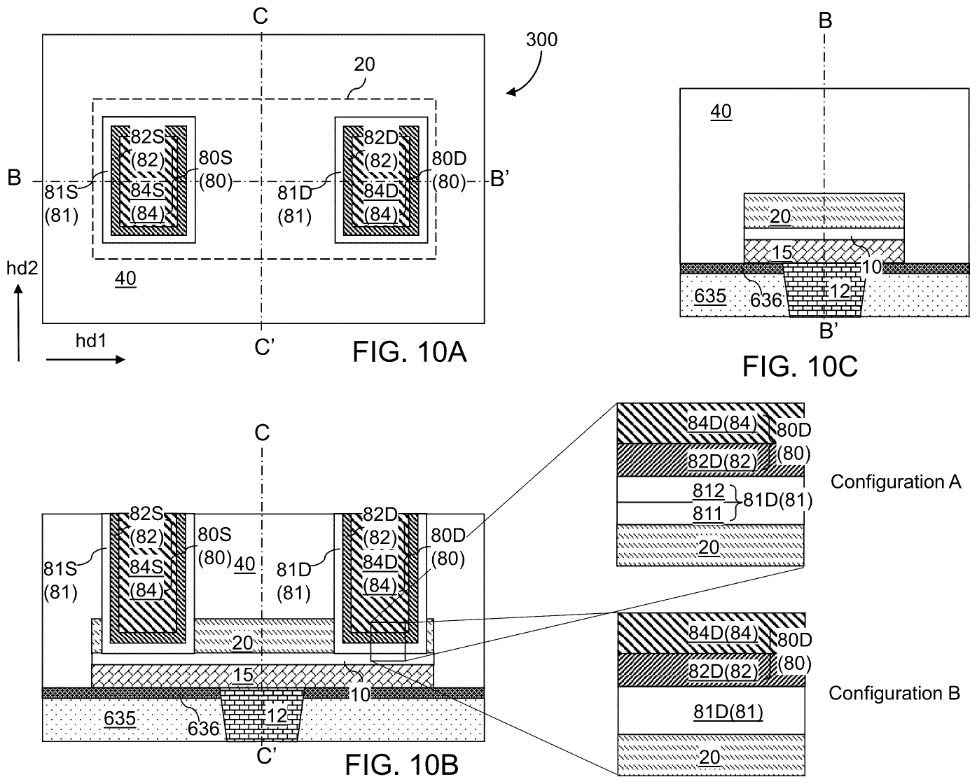

Referring to FIGS. 10A-10C, a second alternative configuration of the first exemplary structure is illustrated after formation of a source electrode 80S and a drain electrode 80D according to an embodiment of the present disclosure. The second alternative configuration of the first exemplary structure may be formed by extending the etch depth of the anisotropic etch process that forms the source cavity 51 and the drain cavity 59 at the processing steps of FIGS. 6A-6C such that bottom surfaces of the source cavity 51 and the drain cavity 59 are formed on top surface segments of the gate dielectric 10. Thus, each of the source cavity 51 and the drain cavity 59 vertically extends through the active layer 20 until the top surface of the gate dielectric 10 is exposed underneath each of the source cavity 51 and the drain cavity 59. The bottom surface of each tunneling dielectric barrier liner 81 may contact a respective surface segment of the top surface of the gate dielectric 10.

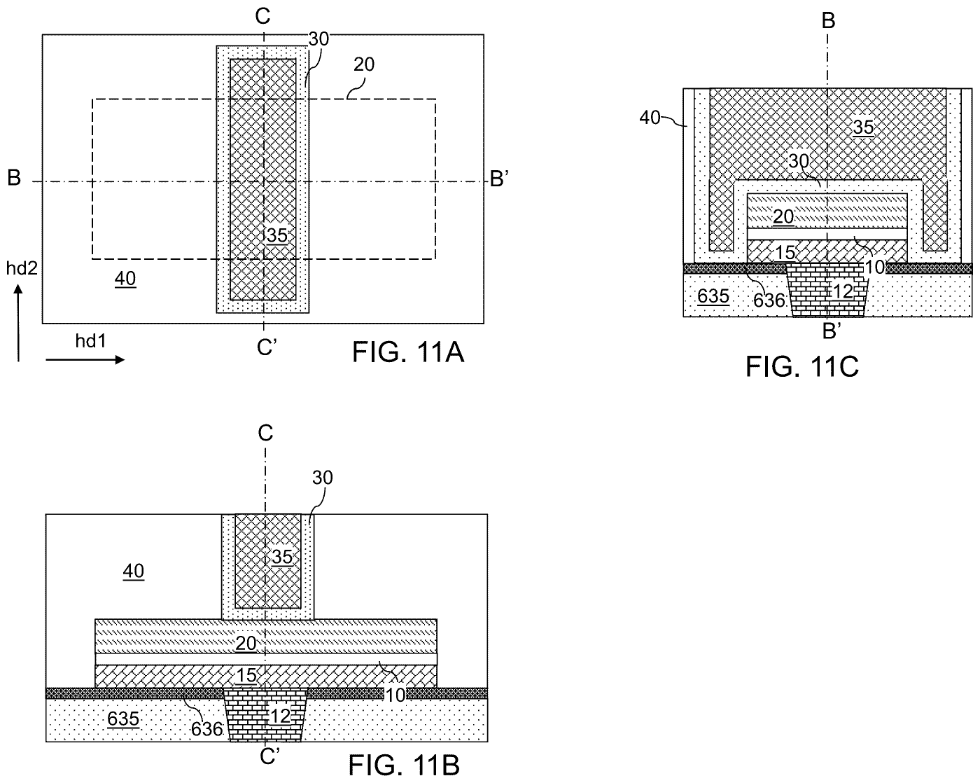

Referring to FIGS. 11A-11C, a third alternative configuration of the first exemplary structure may be derived from the first exemplary structure illustrated in FIGS. 5A-5C by forming a top gate cavity that straddles over the active layer 20 along the second horizontal direction hd2. In one embodiment, the top gate cavity may have a greater lateral extent along the second horizontal direction hd2 than the active layer 20, and sidewalls of the stack (20, 10, 15) including the gate electrode 15, the gate dielectric 10, and the active layer 20 may be physically exposed on both sides of the active layer 20. Further, a top surface segments of the etch stop dielectric layer 636 may be physically exposed on both sides of the active layer 20.

A top gate structure (30, 35) including a top gate dielectric 30 and the top gate electrode 35 may be formed in the top gate cavity. In one embodiment, the top gate electrode 35 may comprise two wing portions that vertically extend downward from a horizontally extending portion of the top gate electrode 35 which straddles the active layer 20 along the second horizontal direction hd2.

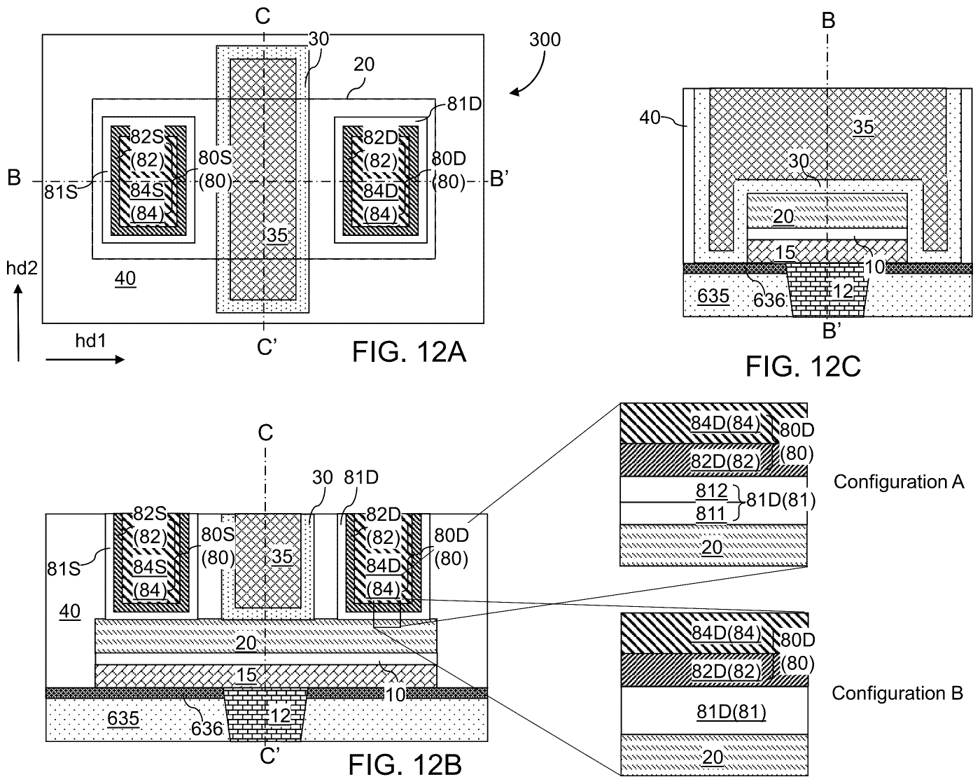

Referring to FIGS. 12A-12C, the processing steps described with reference to FIGS. 6A-8C may be performed to form a source cavity 51 and the drain cavity 59 through the insulating layer 40 over each active layer 20, and to form a source electrode 80S in each source cavity 51 and to form a drain electrode 80D in each drain cavity 59.

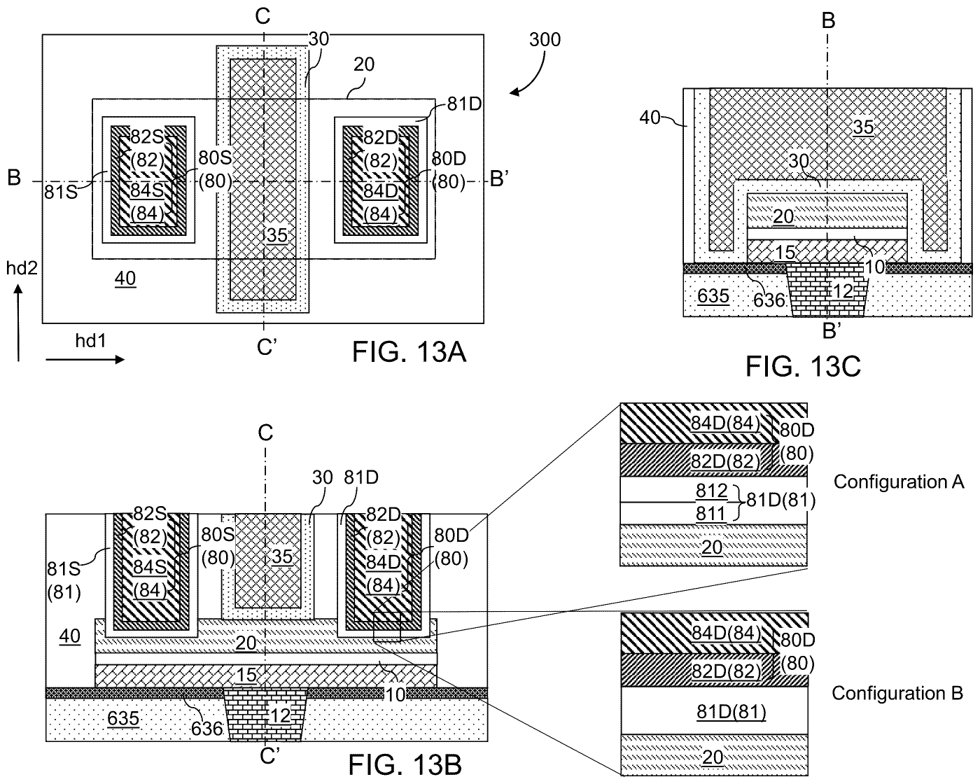

Referring to FIGS. 13A-13C, a fourth alternative configuration of the first exemplary structure may be derived from the third alternative configuration of the first exemplary structure illustrated in FIGS. 12A-12C by vertically extending the source via cavity 51 and the drain via cavity 59 as described with reference to FIGS. 9A-9C. Portions of the active layer 20 may be vertically recessed underneath the source cavity 51 and the drain cavity 59, and sidewalls of the tunneling dielectric barrier liner 81 may contact sidewalls of recessed portions of the active layer 20 upon deposition of the tunneling dielectric barrier liner 81. The bottom surface of each tunneling dielectric barrier liner 81 may contact a respective recessed horizontal surface segment of the active layer 20.

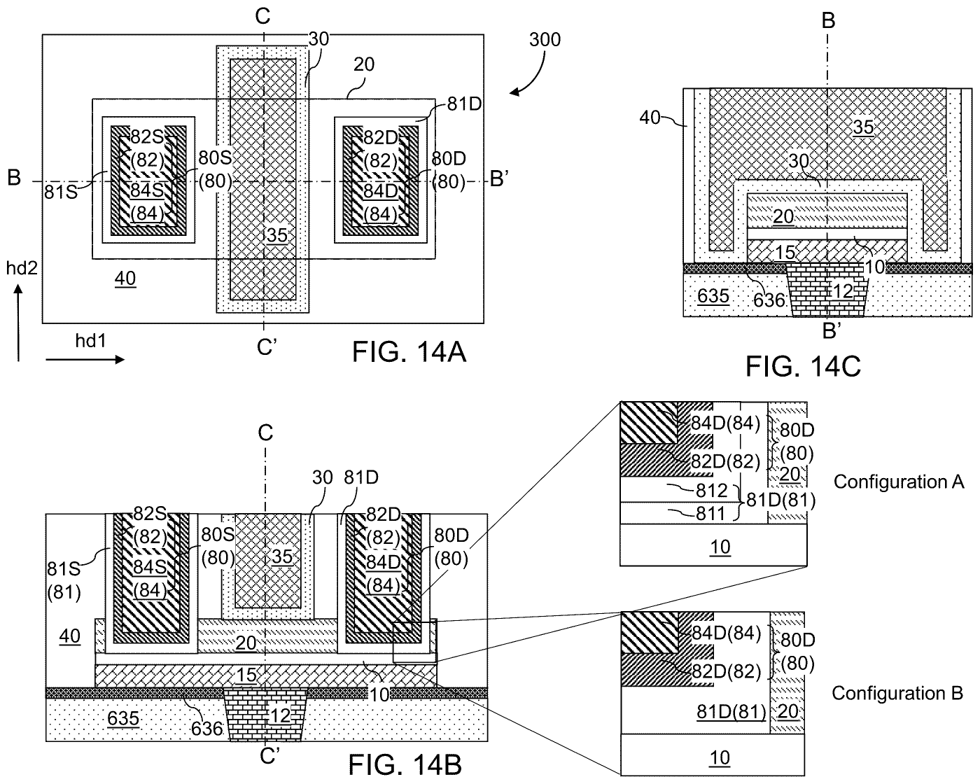

Referring to FIGS. 14A-14C, a fifth alternative configuration of the first exemplary structure may be derived from the third alternative configuration of the first exemplary structure illustrated in FIGS. 12A-12C by vertically extending the source via cavity 51 and the drain via cavity 59 as described with reference to FIGS. 10A-10C. Thus, each of the source cavity 51 and the drain cavity 59 vertically extends through the active layer 20 until the top surface of the gate dielectric 10 is exposed underneath each of the source cavity 51 and the drain cavity 59. The bottom surface of each tunneling dielectric barrier liner 81 may contact a respective surface segment of the top surface of the gate dielectric 10.

Referring collectively to FIGS. 1-14C, a semiconductor structure is provided, which comprises a stack (20, 10, 15) overlying a dielectric material layer (601, 610, 620) that is located over a substrate 8, wherein the stack (20, 10, 15) comprise a gate electrode 15, a gate dielectric 10, and an active layer 20 comprising a p-type tin oxide semiconductor material; a source electrode 80S and a drain electrode 80D that are spaced from each other by a portion of an insulating layer 40; and at least one tunneling dielectric barrier liner (81S, 81D) located on a surface of the active layer 20, wherein each of the source electrode 80S and the drain electrode 80D is spaced from the active layer 20 by the at least one tunneling dielectric barrier liner (81S, 81D).

In one embodiment, the insulating layer 40 overlies the stack (20, 10, 15); each of the source electrode 80S and the drain electrode 80D vertically extends through the insulating layer 40; and each of the source electrode 80S and the drain electrode 80D has a respective top surface located within a horizontal plane including a top surface of the insulating layer 40. In one embodiment, the at least one tunneling dielectric barrier liner (81S, 81D) comprises a single tunneling dielectric barrier liner (81S, 81D) (i.e., a single continuous layer embodying the tunneling dielectric barrier liner 81) contacting a sidewall of the insulating layer 40, and contacting a sidewall of one of the source electrode 80S and the drain electrode 80D.

In one embodiment, the tunneling dielectric barrier liner (81S, 81D) comprises at least one material selected from alkaline-earth metal oxides. In one embodiment, each tunneling dielectric barrier liner (81S, 81D) comprises a material selected from a dielectric oxide of a light Group 13 element, a transition metal oxide having a band gap larger than 3.0 eV, an oxygen-free nitride of a light Group 13 element, and silicon nitride. Each tunneling dielectric barrier liner (81S, 81D) may comprise a stack of at least two component tunneling dielectric barrier liners having different material compositions after completion of manufacturing processes. In some embodiments, the at least two component tunneling dielectric barrier liners may partially interdiffuse into each other or among one another to form a tunneling dielectric barrier liner (81S, 81D) having a graded material composition. Alternatively, the at least two component tunneling dielectric barrier liners may completely interdiffuse into each other or among one another to form a homogenized the tunneling dielectric barrier liner (81S, 81D).

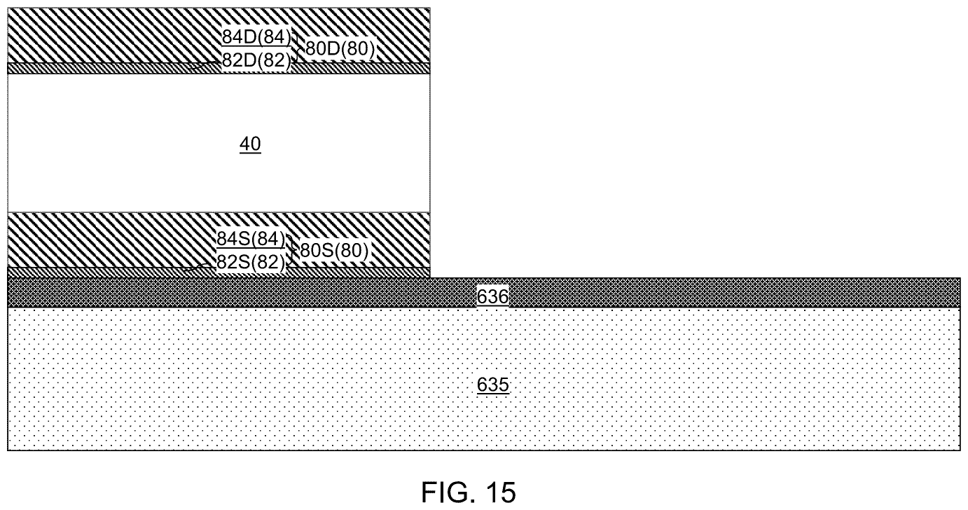

Referring to FIG. 15, a region of a second exemplary structure is illustrated after formation a source electrode 80S, an insulating layer 40, and a drain electrode 80D according to an embodiment of the present disclosure. The second exemplary structure may be derived from the first exemplary structure illustrated in FIG. 1 by sequentially forming a layer stack including, from bottom to top, at least one first electrically conductive material layer, the insulating layer 40, and at least one second electrically conductive material layer. The layer stack may be subsequently patterned, for example by applying a photoresist layer above the layer stack, lithographically patterning the photoresist layer, and transferring the pattern in the photoresist layer through the layer stack by performing an anisotropic etch process. The photoresist layer may be subsequently removed, for example, by ashing.

The patterned portion of the at least one first electrically conductive layer may comprise a first electrode, which may be a source electrode 80S or a drain electrodes 80D. The patterned portion of the at least one second electrically conductive layer may comprise a second electrode, which may be a drain electrode 80D or a source electrode 80S. Generally, an assembly of a source electrode 80S, a drain electrode 80D, and an insulating layer 40 extending between the source electrode 80S and the drain electrode 80D may be formed over the dielectric material layers (601, 610, 620) which overlie the substrate 8. In one embodiment, the components of the assembly (80S, 40, 80D) may be arranged along the vertical direction such that the drain electrode 80D overlies, or underlies, the source electrode 80S. While the present disclosure is described using an embodiment in which the drain electrode 80D overlies the source electrode 80S, embodiments are expressly contemplated herein in which the source electrode 80S overlies the drain electrode 80D.

In one embodiment, the at least one first electrically conductive layer may comprise a layer stack of a source metallic barrier liner layer and a first high-conductivity metal layer. In this embodiment, the source electrode 80S may comprise a layer stack of a source metallic barrier liner 82S comprising a patterned portion of the source metallic barrier liner layer, and a source metal portion 84S comprising a patterned portion of the first high-conductivity metal layer. Likewise, the at least one second electrically conductive layer may comprise a layer stack of a drain metallic barrier liner layer comprising a patterned portion of the drain metallic barrier liner layer, and a second high-conductivity metal layer. In this embodiment, the drain electrode 80D may comprise a layer stack of a drain metallic barrier liner 82D and a drain metal portion 84D comprising a patterned portion of the second high-conductivity metal layer.

Sidewalls of each structure in the assembly (80S, 40, 80D) of a source electrode 80S, the insulating layer 40, and a drain electrode 80D may be vertically coincident, i.e., may be located within a same vertical plane. The source electrode 80S and the drain electrode 80D are collectively referred to as source/drain electrodes 80. Generally, one or more of the source/drain electrodes 80 may comprise a vertical stack of a respective metallic barrier liner 82 and a respective metal plate 84. Each metallic barrier liner 82 may include one or more of TiN, TaN, WN, and MoN. each metal plate make include one or more of Cu, W, Mo, Ti, Ta, Co, Ru, etc. The thickness of each source/drain electrode 80 may be in a range from 10 nm to 300 nm, such as from 30 nm to 100 nm, although lesser and greater thicknesses may also be used. The thickness of the insulating layer 40 determines the channel length of the thin-film transistor to be subsequently formed. The thickness of the insulating layer 40 may be in a range from 10 nm to 500 nm, such as from 14 nm to 100 nm, although lesser and greater thicknesses may also be used.

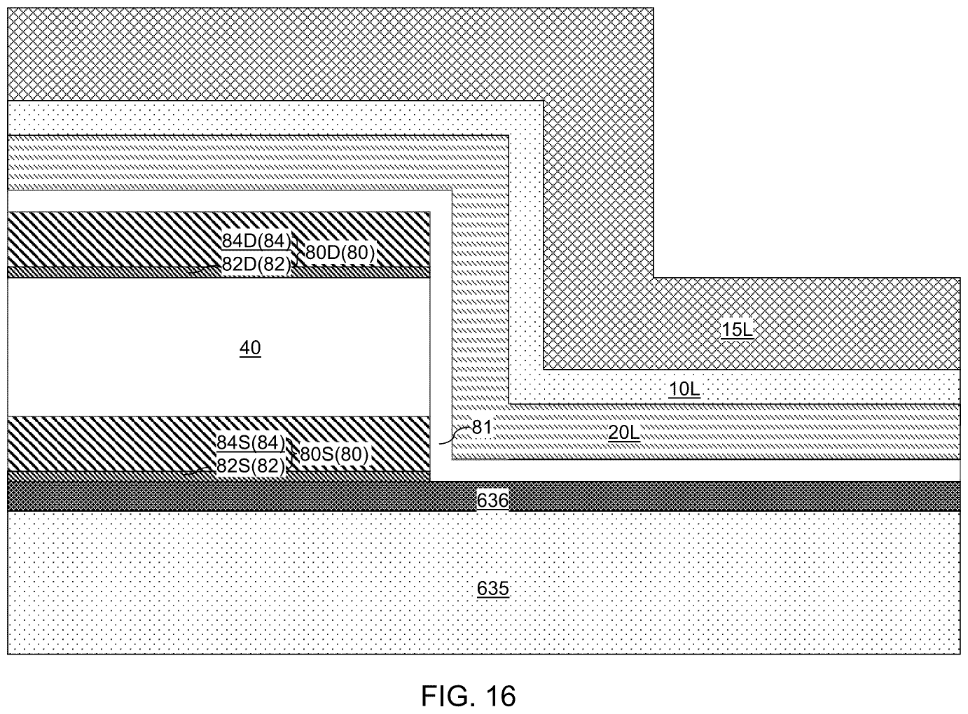

Referring to FIG. 16, a tunneling dielectric barrier liner 81 may be deposited on the physically exposed surfaces of the assembly (80S, 40, 80D) and on the top surface of the etch stop dielectric layer 636. The tunneling dielectric barrier liner 81 in the second exemplary structure may have the same structure and the thickness range as any configuration of the tunneling dielectric barrier liner 81 discussed with reference to FIGS. 7A-7C. In other words, any embodiment of the tunneling dielectric barrier liner 81 discussed with reference to FIGS. 7A-7C may be used in the second exemplary structure. The deposition of tunneling dielectric barrier liner 81 may be conformal, so that a thickness of segments that extend in a horizontal direction is nominally equal to a thickness of segments that extend in a vertical direction. The deposition of tunneling dielectric barrier liner 81 may also be non-conformal. The deposition process will be optimized for the thickness of the vertical segments.

Subsequently, a semiconductor material layer 20L, a gate dielectric material layer 10L, and a gate electrode material layer 15L may be sequentially deposited over the tunneling dielectric barrier liner 81. Each of the semiconductor material layer 20L, the gate dielectric material layer 10L, and the gate electrode material layer 15L may have the same structure and the thickness range as discussed with reference to FIGS. 3A-3C.

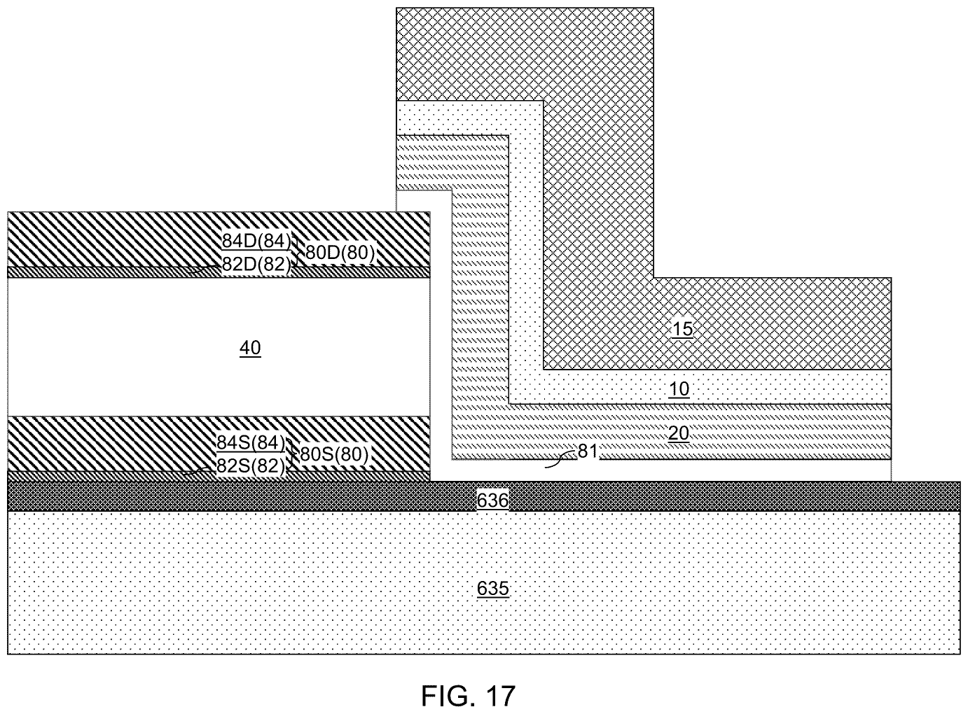

Referring to FIG. 17, a photoresist layer (not shown) may be applied over the gate electrode material layer 15L, and may be lithographically patterned to cover an area overlying a vertically extending surface including sidewalls of the source electrode 80S, the insulating layer 40, and the drain electrode 80D. An anisotropic etch process may be performed to etch unmasked portions of the gate electrode material layer 15L, the gate dielectric material layer 10L, the semiconductor material layer 20L, and the tunneling dielectric barrier liner 81. The photoresist layer may be subsequently removed, for example, by ashing. A remaining portion of the gate electrode material layer 15L comprises a gate electrode 15. A remaining portion of the gate dielectric material layer 10L comprises a gate dielectric 10. A remaining portion of the semiconductor material layer 20L comprises an active layer 20. As discussed above, the active layer comprises a tin oxide semiconductor material in which the atomic ratio of oxygen atoms to tin atoms is in a range from 0.95 to 1.15.

Generally, a stack (20, 10, 15) including a gate electrode 15, a gate dielectric 10, and an active layer 20 comprising a tin oxide semiconductor material may be formed over a dielectric material layer (601, 610, 620) which overlies a substrate 8. During formation of the second exemplary structure, the stack (20, 10, 15) is formed after formation of an assembly (80S, 40, 80D) of a source electrode 80S, the insulating layer 40, and a drain electrode 80D. The tunneling dielectric barrier liner 81 is in contact with the active layer 20, the source electrode 80S, and the drain electrode 80D after formation of the stack (20, 10, 15) and the assembly (80S, 40, 80D).

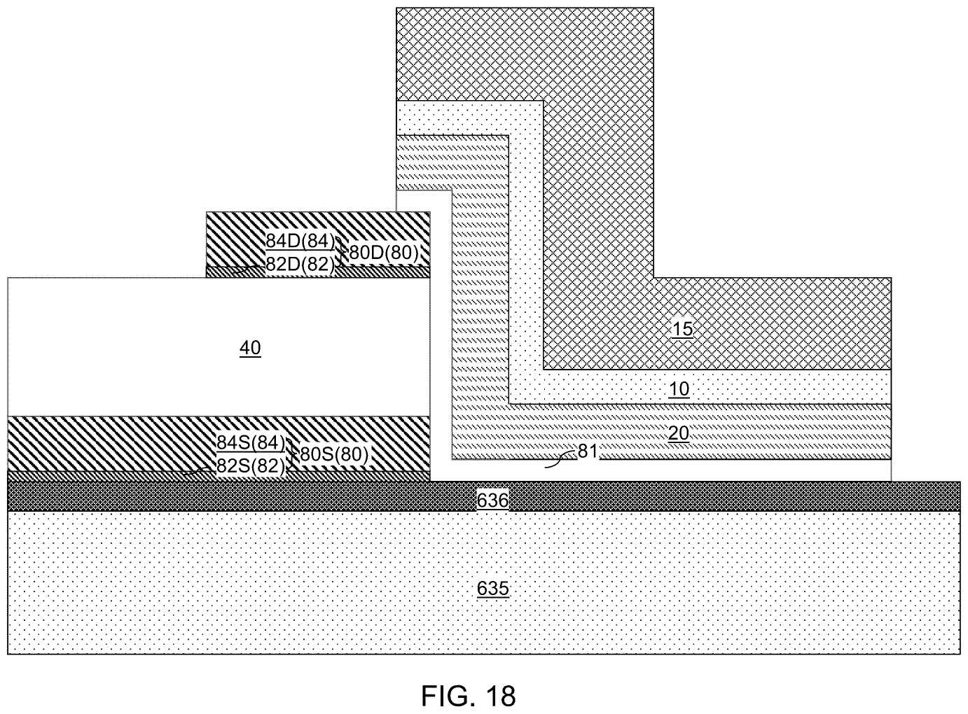

Referring to FIG. 18, a photoresist layer may be applied over the second exemplary structure, and may be lithographically patterned to form an opening in an area that overlies a portion of the source electrode 80S that is distal from the vertical interface between the tunneling dielectric barrier liner 81 and the assembly (80S, 40, 80D) of the source electrode 80S, the insulating layer 40, and the drain electrode 80D. An anisotropic etch process may be performed to etch unmasked portions of the drain electrode 80D. A distal portion of the drain electrode 80D that is distal from the vertical interface is removed, while a proximal portion of the drain electrode 80D that is proximal to the vertical interface remains after the anisotropic etch process. The photoresist layer may be subsequently removed, for example by ashing.

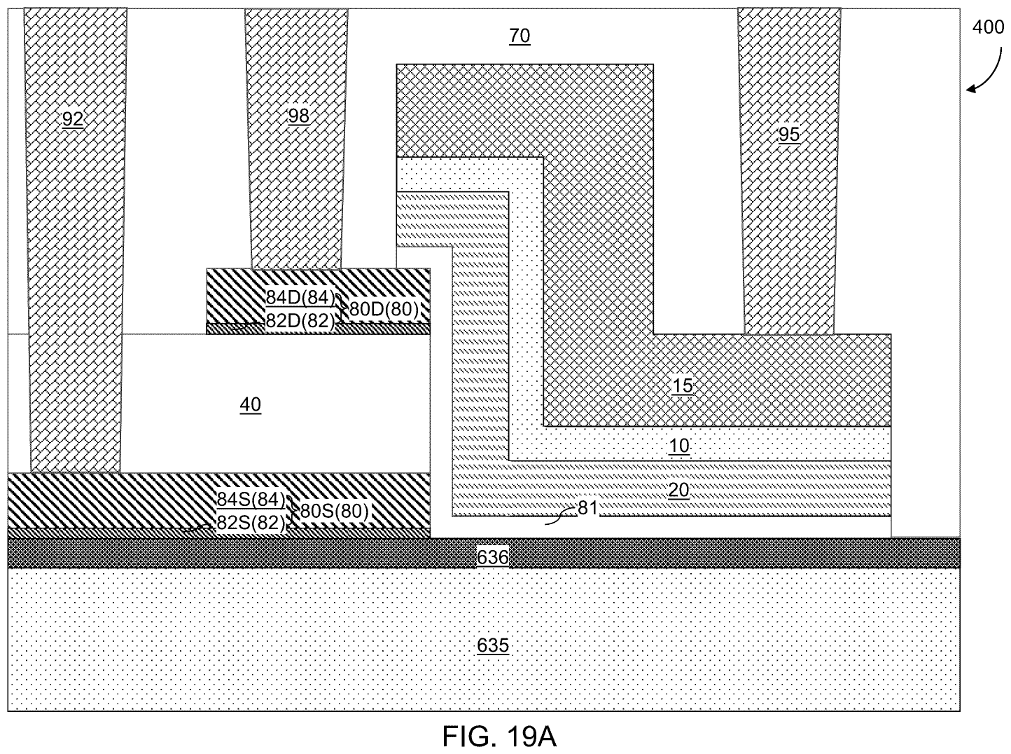

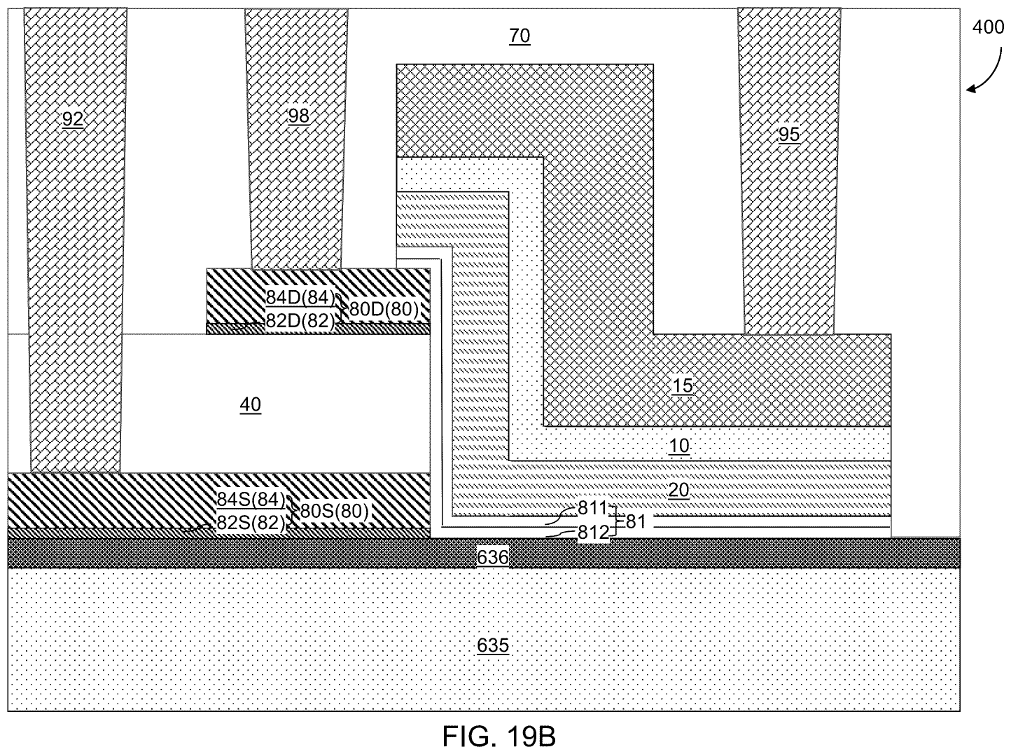

Referring to FIGS. 19A and 19B, a dielectric material such as undoped silicate glass or a doped silicate glass may be deposited over the gate electrode 15, the drain electrode 80D, the insulating layer 40, and the etch stop dielectric layer 636. A planarization process, such as a chemical mechanical planarization process, may be performed to planarized the top surface of the deposited dielectric material. The remaining portion of the deposited dielectric material covers the gate electrode 15, the drain electrode 80D, the insulating layer 40, and the etch stop dielectric layer 636, and is herein referred to as contact-level dielectric layer 70.

Various contact via structures (92, 95, 98) may be formed through the contact-level dielectric layer 70. The various contact via structures (92, 95, 98) may comprise a source contact via structure 92 that contacts a top surface of the source electrode 80S, a drain contact via structure 98 that contacts a top surface of the drain electrode 80D, and the gate contact via structure 95 that contacts a top surface of the gate electrodes 15. A thin-film transistor 400 is thus formed. FIG. 19A illustrates a configuration in which the tunneling dielectric barrier liner 81 consists of a single tunneling dielectric barrier liner having a homogeneous material composition throughout. FIG. 19B illustrates a configuration in which the tunneling dielectric barrier liner 81 comprises a stack of at least two component dielectric diffusion barrier liners (such as at least two alkaline-earth metal oxide layers (811, 812)) having different material compositions after completion of the manufacturing processes.

Referring collectively to FIGS. 15-19B, a semiconductor structure is provided, which comprises a stack (20, 10, 15) overlying a dielectric material layer (601, 610, 620) that is located over a substrate 8, wherein the stack (20, 10, 15) comprise a gate electrode 15, a gate dielectric 10, and an active layer 20 comprising a tin oxide semiconductor material; a source electrode 80S and a drain electrode 80D that are spaced from each other by a portion of an insulating layer 40; and at least one tunneling dielectric barrier liner 81 located on a surface of the active layer 20, wherein each of the source electrode 80S and the drain electrode 80D is spaced from the active layer 20 by the at least one tunneling dielectric barrier liner 81.

In one embodiment, each of the source electrode 80S and the drain electrode 80D overlies or underlies the insulating layer 40; and the at least one tunneling dielectric barrier liner 81 comprises a single tunneling dielectric barrier liner 81 (i.e., a single continuous layer embodying the tunneling dielectric barrier liner 81) contacting a sidewall of the source electrode 80S, a sidewall of the insulating layer 40, and a sidewall of the drain electrode 80D.

In one embodiment, the tunneling dielectric barrier liner 81 comprises at least one material selected from alkaline-earth metal oxides. In one embodiment, each tunneling dielectric barrier liner 81 comprises a material selected from a dielectric oxide of a light Group 13 element, a transition metal oxide having a band gap larger than 3.0 eV, an oxygen-free nitride of a light Group 13 element, and silicon nitride. Each tunneling dielectric barrier liner 81 may comprise a stack of at least two component dielectric diffusion barrier liners (such as at least two alkaline-earth metal oxide layers (811, 812)) having different material compositions after completion of the manufacturing processes. In some embodiments, the at least two component dielectric diffusion barrier liners may partially interdiffuse into each other or among one another to form a tunneling dielectric barrier liner 81 having a graded material composition. Alternatively, the at least two component dielectric diffusion barrier liners may completely interdiffuse into each other or among one another to form a homogenized the tunneling dielectric barrier liner 81.

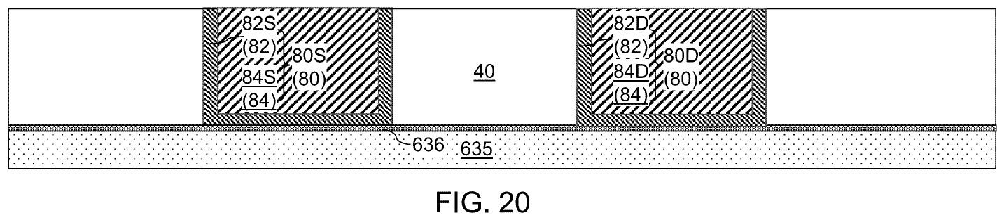

Referring to FIG. 20, a region of a third exemplary structure is illustrated after formation of a source electrode 80S and a drain electrode 80D in an insulating layer 40 according to an embodiment of the present disclosure. The third exemplary structure may be derived from the first exemplary structure illustrated in FIG. 1 by forming an insulating layer 40 over the etch stop dielectric layer 636. The insulating layer 40 comprises an insulating material such as undoped silicate glass or a doped silicate glass. The thickness of the insulating layer 40 may be in a range from 50 nm to 300 nm, such as from 100 nm to 200 nm, although lesser and greater thicknesses may also be used.

A photoresist layer (not shown) may be applied over the insulating layer 40, and may be lithographically patterned to form a pair of elongated openings in each region in which a thin-film transistor is to be subsequently formed. The pair of elongated openings may be laterally spaced from each other by a uniform lateral spacing, which is the channel length of the thin-film transistor to be subsequently formed. The channel length may be in a range from 10 nm to 500 nm, such as from 14 nm to 100 nm, although lesser and greater channel lengths may also be used. An anisotropic etch process may be performed to transfer the pattern of the elongated openings through the insulating layer 40. The etch stop dielectric layer 636 may function as an etch stop structure during the anisotropic etch process. A source cavity and a drain cavity may be formed through the insulating layer 40 underneath a pair of elongated openings in the photoresist layer. In one embodiment, a surface segment of the top surface of the etch stop dielectric layer 636 may be physically exposed underneath each of the source cavity and the drain cavity. The photoresist layer may be subsequently removed, for example, by ashing.

At least one conductive material, such as at least one metallic material, may be deposited in the source cavity and drain cavity and over the insulating layer 40. The at least one conductive material may include a metallic barrier liner layer including metallic barrier liner material and a metallic fill material layer including a metallic fill material. The metallic barrier liner material may include a conductive metallic nitride or a conductive metallic carbide such as TIN, TaN, WN, TiC, TaC, and/or WC. The metallic fill material may include W, Cu, Al, Co, Ru, Mo, Ta, Ti, alloys thereof, and/or combinations thereof. Other suitable metallic barrier liner and metallic fill materials within the contemplated scope of disclosure may also be used.

Portions of the at least one metallic material may be removed from outside the source cavity and the drain cavity by a planarization process, which may use a chemical mechanical polishing (CMP) process and/or a recess etch process. Each remaining portion of the at least one conductive material filling a source cavity constitutes a source electrode 80S. Each remaining portion of the at least one conductive material filling a drain cavity constitutes a drain electrode 80D.

In one embodiment, each source electrode 80S may include a source metallic barrier liner 82S that is a remaining portion of the metallic barrier liner material, and a source metal portion 84S that is a remaining portion of the metallic fill material. Each drain electrode 80D may include a drain metallic barrier liner 82D that is a remaining portion of the metallic barrier liner material, and a drain metal portion 84D that is a remaining portion of the metallic fill material. The source electrode 80S may be formed in the source cavity, and the drain electrode 80D may be in the drain cavity. The source electrode 80S and the drain electrode 80D may be formed on the horizontal surface segments of the top surface of the etch stop dielectric layer 636, respectively.

A source electrode 80S and a drain electrode 80D may be formed within the insulating layer 40. Thus, an assembly of a source electrode 80S, a drain electrode 80D, and an insulating layer 40 extending between the source electrode 80S and the drain electrode 80D may be formed over the dielectric material layer (601, 610, 620). In one embodiment, top surfaces of the source electrode 80S, the drain electrode 80D, and the insulating layer may be formed within a same horizontal plane.

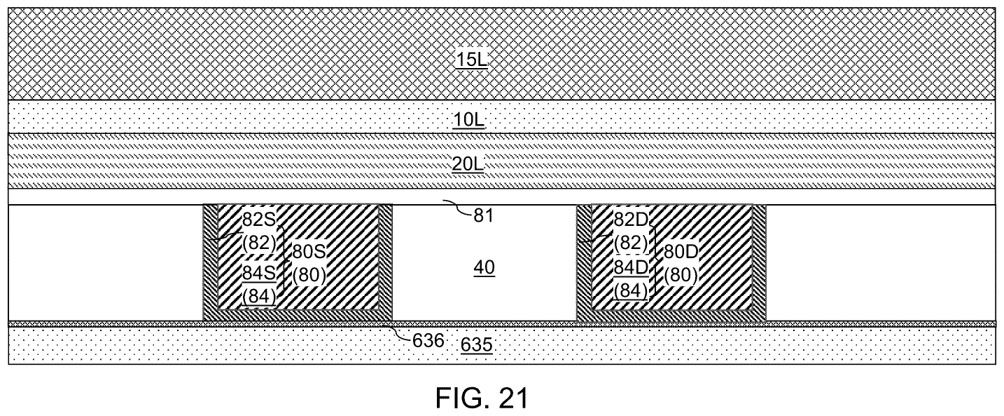

Referring to FIG. 21, a tunneling dielectric barrier liner 81 may be conformally deposited on the physically exposed surfaces of the assembly (80S, 40, 80D). The tunneling dielectric barrier liner 81 in the third exemplary structure may have the same structure and the thickness range as any configuration of the tunneling dielectric barrier liner 81 discussed with reference to FIGS. 7A-7C. In other words, any embodiment of the tunneling dielectric barrier liner 81 discussed with reference to FIGS. 7A-7C may be used in the third exemplary structure.

Subsequently, a semiconductor material layer 20L, a gate dielectric material layer 10L, and a gate electrode material layer 15L may be sequentially deposited over the tunneling dielectric barrier liner 81. Each of the semiconductor material layer 20L, the gate dielectric material layer 10L, and the gate electrode material layer 15L may have the same structure and the thickness range as discussed with reference to FIGS. 3A-3C.

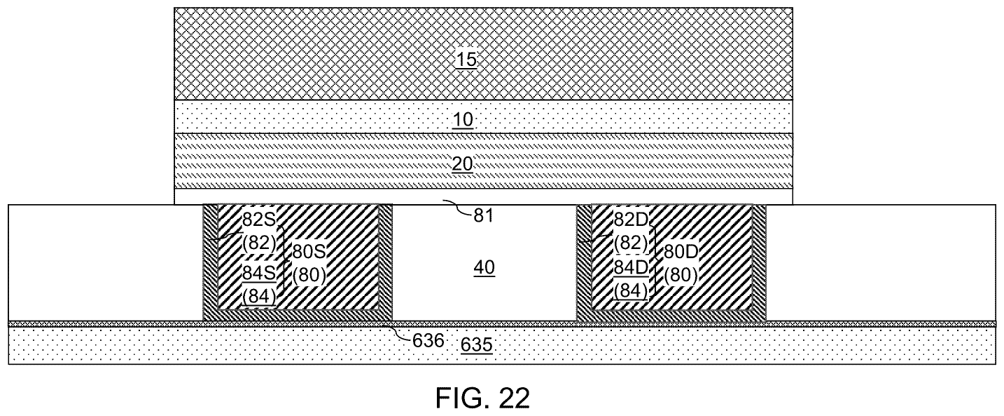

Referring to FIG. 22, a photoresist layer (not shown) may be applied over the gate electrode material layer 15L, and may be lithographically patterned to cover an area that extends over the source electrode 80S, the drain electrode 80D, and the portion of the insulating layer 40 that extends between the source electrode 80S and the drain electrode 80D. An anisotropic etch process may be performed to etch unmasked portions of the gate electrode material layer 15L, the gate dielectric material layer 10L, the semiconductor material layer 20L, and the tunneling dielectric barrier liner 81. The photoresist layer may be subsequently removed, for example, by ashing. A remaining portion of the gate electrode material layer 15L comprises a gate electrode 15. A remaining portion of the gate dielectric material layer 10L comprises a gate dielectric 10. A remaining portion of the semiconductor material layer 20L comprises an active layer 20. As discussed above, the active layer comprises a tin oxide semiconductor material in which the atomic ratio of oxygen atoms to tin atoms is in a range from 0.95 to 1.15.

Generally, a stack (20, 10, 15) including a gate electrode 15, a gate dielectric 10, and an active layer 20 comprising a tin oxide semiconductor material may be formed over a dielectric material layer (601, 610, 620) which overlies a substrate 8. During formation of the third exemplary structure, the stack (20, 10, 15) is formed after formation of an assembly (80S, 40, 80D) of a source electrode 80S, the insulating layer 40, and a drain electrode 80D. The tunneling dielectric barrier liner 81 is in contact with the active layer 20, the source electrode 80S, and the drain electrode 80D after formation of the stack (20, 10, 15) and the assembly (80S, 40, 80D).

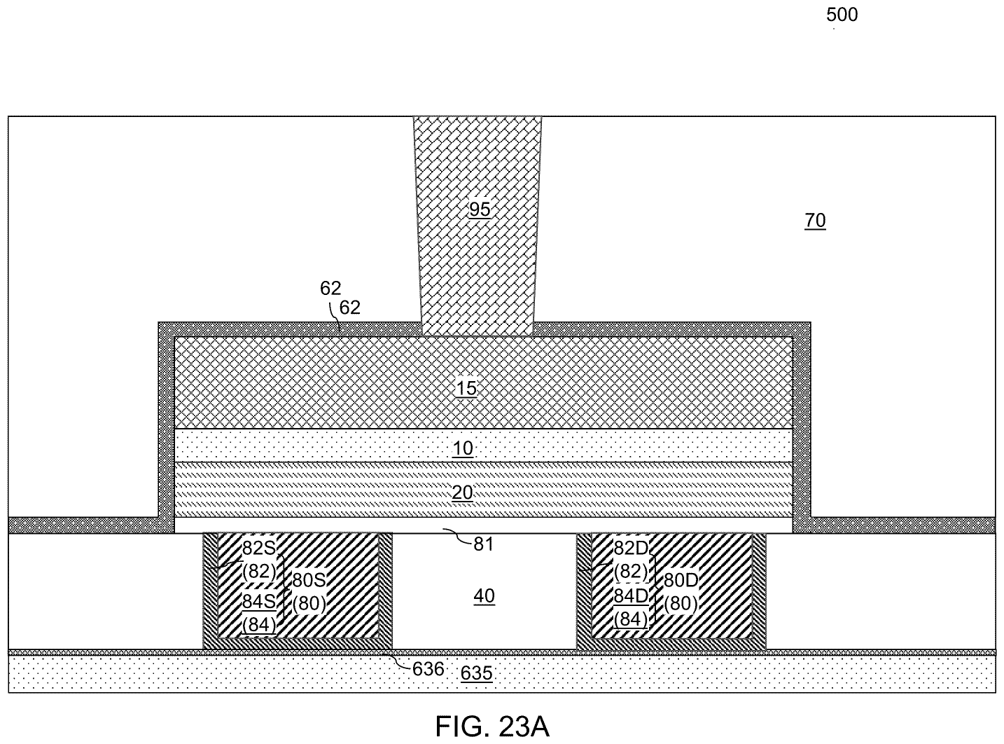

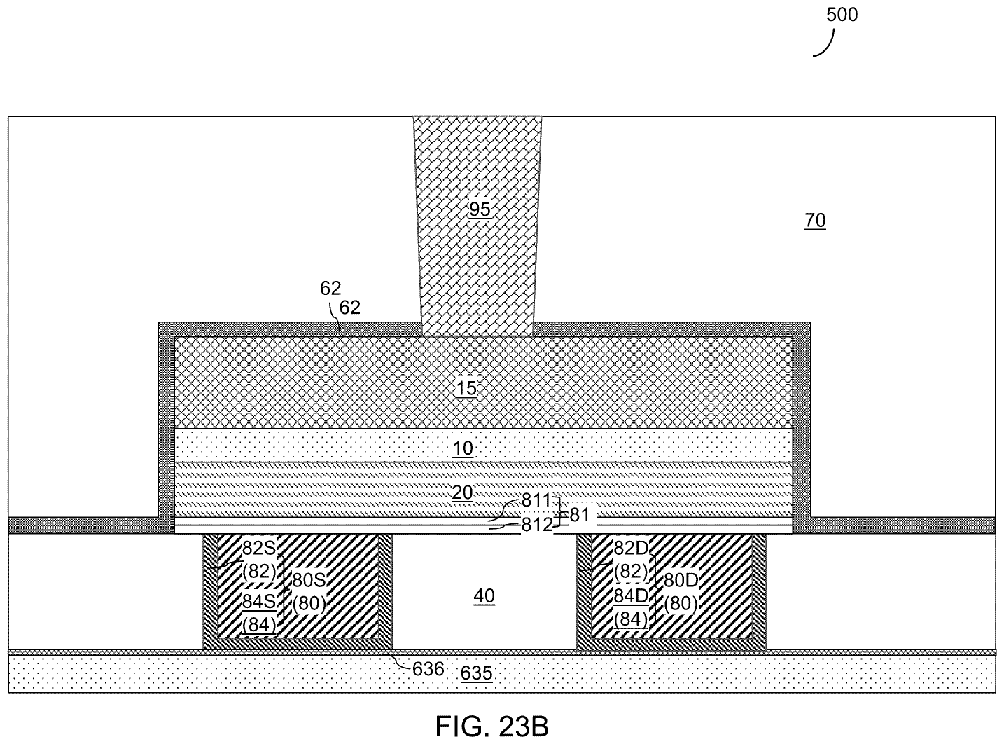

Referring to FIGS. 23A and 23B, an optional dielectric passivation layer 62 may be deposited over, and around, the stack (20, 10, 15) including the gate electrode 15, the gate dielectric 10, and the active layer 20 and above a physically exposed portion of the top surface of the insulating layer 40. The dielectric passivation layer 62, if used, comprises a dielectric material that may function as a diffusion barrier material. For example, the dielectric passivation layer 62 may comprise silicon nitride, silicon carbide nitride, or silicon oxide nitride.

A dielectric material such as undoped silicate glass or a doped silicate glass may be deposited over the dielectric passivation layer 62, the stack (20, 10, 15), and the insulating layer 40. A planarization process, such as a chemical mechanical planarization process, may be performed to planarized the top surface of the deposited dielectric material. The remaining portion of the deposited dielectric material covers the gate electrode 15, the drain electrode 80D, the insulating layer 40, and the etch stop dielectric layer 636, and is herein referred to as contact-level dielectric layer 70.

Various contact via structures may be formed through the contact-level dielectric layer 70. The various contact via structures (92, 95, 98) may comprise a source contact via structure (not shown) that contacts a top surface of the source electrode 80S, a drain contact via structure (not shown) that contacts a top surface of the drain electrode 80D, and the gate contact via structure 95 that contacts a top surface of the gate electrodes 15. A thin-film transistor 500 is thus formed. FIG. 23A illustrates a configuration in which the tunneling dielectric barrier liner 81 consists of a single tunneling dielectric barrier liner having a homogeneous material composition throughout. FIG. 23B illustrates a configuration in which the tunneling dielectric barrier liner 81 comprises a stack of at least two component dielectric diffusion barrier liners (such as at least two alkaline-earth metal oxide layers (811, 812)) having different material compositions after completion of the manufacturing processes.

Referring collectively to FIGS. 20-23, a semiconductor structure is provided, which comprises a stack (20, 10, 15) overlying a dielectric material layer (601, 610, 620) that is located over a substrate 8, wherein the stack (20, 10, 15) comprise a gate electrode 15, a gate dielectric 10, and an active layer 20 comprising a tin oxide semiconductor material; a source electrode 80S and a drain electrode 80D that are spaced from each other by a portion of an insulating layer 40; and at least one tunneling dielectric barrier liner 81 located on a surface of the active layer 20, wherein each of the source electrode 80S and the drain electrode 80D is spaced from the active layer 20 by the at least one tunneling dielectric barrier liner 81.

In one embodiment, the at least one tunneling dielectric barrier liner 81 comprises a single tunneling dielectric barrier liner 81 (i.e., a single continuous layer embodying the tunneling dielectric barrier liner 81) having a planar bottom surface that contacts a top surface of the source electrode 80S, a top surface of the insulating layer 40, and a top surface of the drain electrode 80D.

In one embodiment, the tunneling dielectric barrier liner 81 comprises at least one material selected from alkaline-earth metal oxides. In one embodiment, each tunneling dielectric barrier liner 81 comprises a material selected from a dielectric oxide of a light Group 13 element, a transition metal oxide having a band gap larger than 3.0 eV, an oxygen-free nitride of a light Group 13 element, and silicon nitride. Each tunneling dielectric barrier liner 81 may comprise a stack of at least two component dielectric diffusion barrier liners (such as at least two alkaline-earth metal oxide layers (811, 812)) having different material compositions after completion of the manufacturing processes. In some embodiments, the at least two component dielectric diffusion barrier liners may partially interdiffuse into each other or among one another to form a tunneling dielectric barrier liner 81 having a graded material composition. Alternatively, the at least two component dielectric diffusion barrier liners may completely interdiffuse into each other or among one another to form a homogenized the tunneling dielectric barrier liner 81.

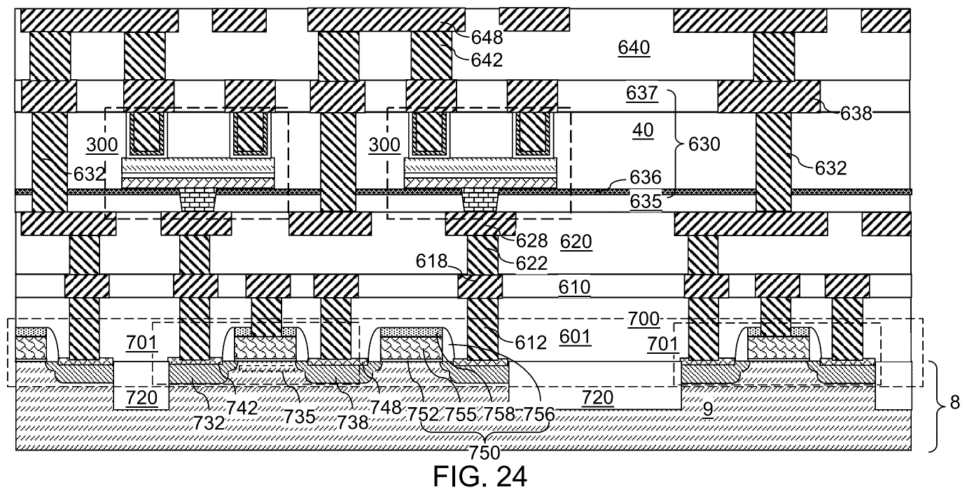

Referring to FIG. 24, the first exemplary structure (discussed with reference to FIGS. 8A-10C and 12A-14C) is illustrated after performing additional processing steps. The first exemplary structure illustrated in FIG. 24 may be derived from any configuration of the first exemplary structure illustrated in FIGS. 8A-10C and 12A-14C by forming second metal via structures 632 through a stack of the insulating material layer 635, the etch stop dielectric layer 636, and the insulating layer 40. The second metal via structures 632 may be formed on top surfaces of the second metal line structures 628. A third line-level dielectric layer 637 may be formed above the insulating layer 40. Third metal line structures 638 may be formed in the third line-level dielectric layer 637 on the top surfaces of the source electrodes 80S, the drain electrodes 80D, and the second metal via structures 632. The combination of the insulating material layer 635, the etch stop dielectric layer 636, the insulating layer 40, and the third line-level dielectric layer 637 constitutes a third interconnect-level dielectric layer 630. The thin-film transistors 300 illustrated in FIGS. 8A-10C and 12A-14C are embedded within the third interconnect-level dielectric layer 630.

A fourth interconnect-level dielectric layer 640 embedding third metal via structures 642 and fourth metal lines 648 may be formed above the third interconnect-level dielectric layer 630. Additional metal interconnect structures (not shown) embedded in additional dielectric material layers (not shown) may be subsequently formed over the fourth interconnect-level dielectric layer 640 as needed.

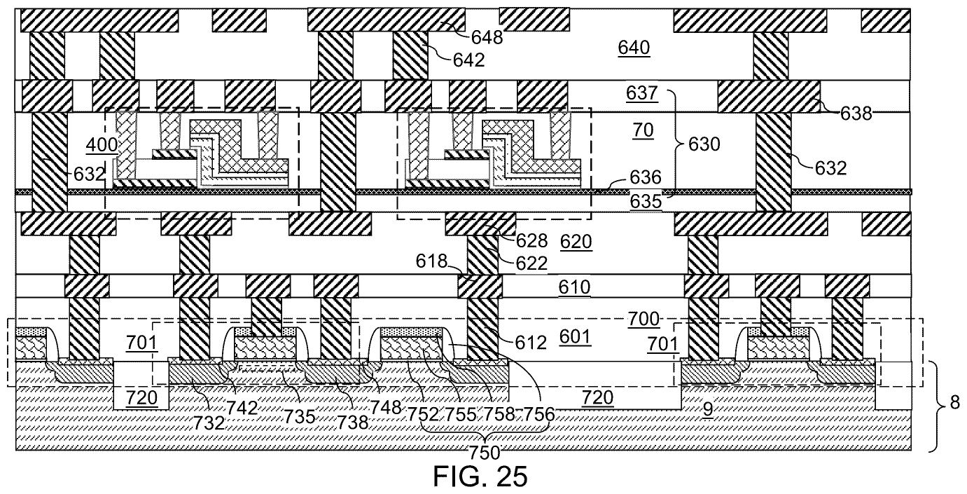

Referring to FIG. 25, the second exemplary structure (discussed with reference to FIG. 19) is illustrated after performing additional processing steps. The second exemplary structure illustrated in FIG. 25 may be derived from the second exemplary structure illustrated in FIG. 19 by forming second metal via structures 632 through a stack of the insulating material layer 635, the etch stop dielectric layer 636, and the contact-level dielectric layer 70. The second metal via structures 632 may be formed on top surfaces of the second metal line structures 628. A third line-level dielectric layer 637 may be formed above the contact-level dielectric layer 70. Third metal line structures 638 may be formed in the third line-level dielectric layer 637 on the top surfaces of the various contact via structures (92, 95, 98), and the second metal via structures 632. The combination of the insulating material layer 635, the etch stop dielectric layer 636, the contact-level dielectric layer 70, and the third line-level dielectric layer 637 constitutes a third interconnect-level dielectric layer 630. The thin-film transistors 400 illustrated in FIG. 19 are embedded within the third interconnect-level dielectric layer 630.

A fourth interconnect-level dielectric layer 640 embedding third metal via structures 642 and fourth metal lines 648 may be formed above the third interconnect-level dielectric layer 630. Additional metal interconnect structures (not shown) embedded in additional dielectric material layers (not shown) may be subsequently formed over the fourth interconnect-level dielectric layer 640 as needed.

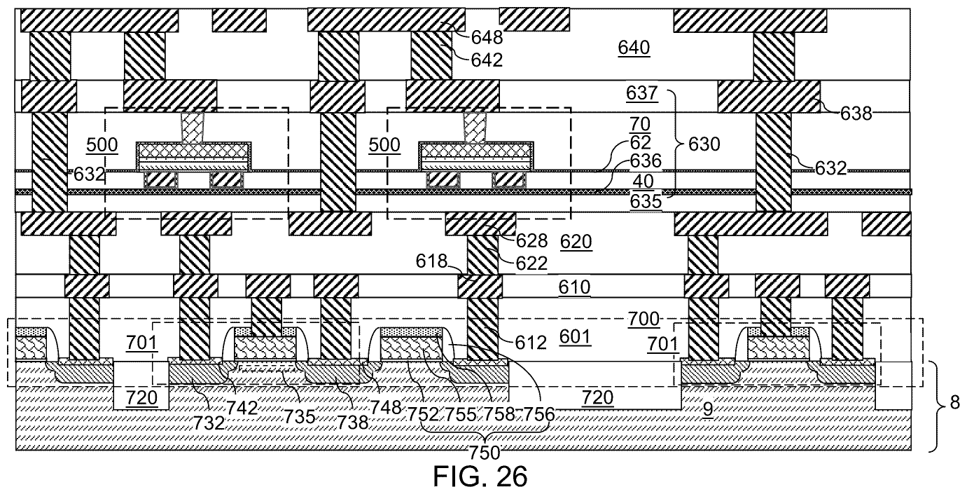

Referring to FIG. 26, the third exemplary structure (discussed with reference to FIG. 23) is illustrated after performing additional processing steps. The third exemplary structure illustrated in FIG. 26 may be derived from the third exemplary structure illustrated in FIG. 26 by forming second metal via structures 632 through a stack of the insulating material layer 635, the etch stop dielectric layer 636, the insulating layer 40, the optional dielectric passivation layer 62, and the contact-level dielectric layer 70. The second metal via structures 632 may be formed on top surfaces of the second metal line structures 628. A third line-level dielectric layer 637 may be formed above the contact-level dielectric layer 70. Third metal line structures 638 may be formed in the third line-level dielectric layer 637 on the top surfaces of the various contact via structures (such as gate contact via structures 95), and the second metal via structures 632. The combination of the insulating material layer 635, the etch stop dielectric layer 636, the insulating layer 40, the optional dielectric passivation layer 62, the contact-level dielectric layer 70, and the third line-level dielectric layer 637 constitutes a third interconnect-level dielectric layer 630. The thin-film transistors 500 illustrated in FIG. 23 are embedded within the third interconnect-level dielectric layer 630.

A fourth interconnect-level dielectric layer 640 embedding third metal via structures 642 and fourth metal lines 648 may be formed above the third interconnect-level dielectric layer 630. Additional metal interconnect structures (not shown) embedded in additional dielectric material layers (not shown) may be subsequently formed over the fourth interconnect-level dielectric layer 640 as needed.

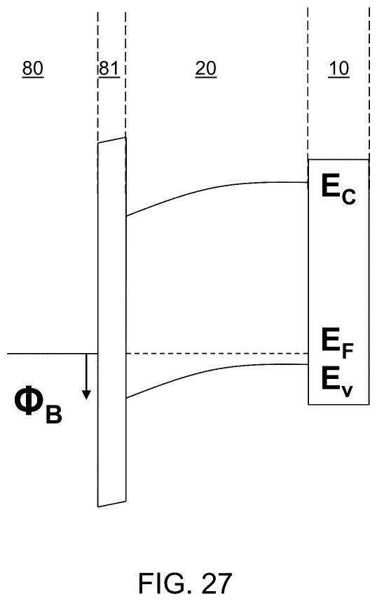

Referring to FIG. 27, a band structure in the vicinity of a tunneling dielectric barrier liner 81 according to an aspect of the present disclosure is illustrated. In the absence of the tunneling dielectric barrier liner 81 of the present disclosure, the electron wave functions from a metallic electrode extend into a tin oxide semiconductor material in an active layer 20. The extension of electron wave function from the metallic electrode into the tin oxide semiconductor material induces formation of metal-induced gap states (MIGS). The MIGS are surface states having discrete energy levels, and anchor the Fermi energy at a mid-gap position within the tin oxide material at the interface, resulting in band bending. This, in turn, presents a substantial energy barrier at the interface for holes, which may be the majority charge carriers in the tin oxide semiconductor material.

According to an aspect of the present disclosure, the presence of the tunneling dielectric barrier liner 81 between a metallic electrode (such as a source electrode 80S or a drain electrode 80D) and a tin oxide semiconductor material in an active layer 20 precludes formation of the MIGS because the electron wavefunction in the metallic electrodes is largely blocked by the tunneling dielectric barrier liner 81. In the illustrated band diagram, E_{c} refers to the conduction band energy, Eᵥ refers to the valence band energy, and E_{F} refers to Fermi energy. The absence of MIGS is illustrated by the absence of any discrete lines representing discrete energy levels at the interface between tunneling dielectric barrier liner 81 and tin oxide channel 20. As discussed above, the material of the tunneling dielectric barrier liner 81 is selected such that the tunneling dielectric barrier liner 81 has a band gap that is greater than 3.0 eV, and preferably greater than 4.0 eV, and more preferably greater than 5.0 eV. Thus, the amplitude of the electron wavefunction decreases rapidly with distance from the metallic electrode within the tunneling dielectric barrier liner 81. This results in a greatly reduced energy barrier for holes, which is denoted as ØB, thereby diminishing the contact resistance across the source/drain electrode 80 and the tin oxide semiconductor material in an active layer 20.

It should be noted that it is critical that the electrons or holes tunnel through the tunneling dielectric barrier liner 81 to provide low contact resistance across the tunneling dielectric barrier liner 81. Thus, the tunneling dielectric barrier liner 81 is sufficiently thin to facilitate tunneling of the holes therethrough. As discussed above, the thickness of the tunneling dielectric barrier liner 81 is in a range from 0.4 nm to 4 nm, and preferably from 0.5 nm to 2 nm, and more preferably from 0.6 nm to 1.2 nm.

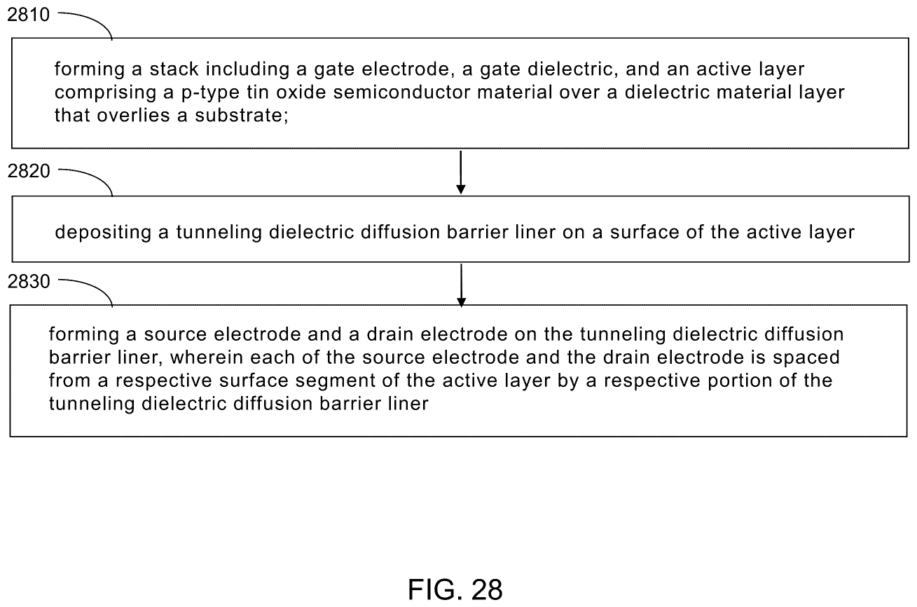

FIG. 28 is a first flowchart that illustrates the general processing steps for manufacturing the semiconductor devices of the present disclosure.

Referring to step 2810 and FIGS. 1-5C and 11A-11C, a stack (20, 10, 15) including a gate electrode 15, a gate dielectric 10, and an active layer 20 comprising a tin oxide semiconductor material may be formed over a dielectric material layer (601, 610, 620) that overlies a substrate 8.

Referring to step 2820 and FIGS. 6A-7C, a tunneling dielectric barrier liner 81 may be deposited on a surface of the active layer 20.

Referring to step 2830 and FIGS. 7A-10C and 12A-14C, a source electrode 80S and a drain electrode 80D may be formed on the tunneling dielectric barrier liner 81. Each of the source electrode 80S and the drain electrode 80D is spaced from a respective surface segment of the active layer 20 by a respective portion of the tunneling dielectric barrier liner 81.

In one embodiment, the method may also include the operations of: depositing an insulating layer 40 over the stack (20, 10, 15); and forming a source cavity 51 and a drain cavity 59 through the insulating layer 40, wherein the tunneling dielectric barrier liner 81 is deposited in peripheral regions of the source cavity 51 and the drain cavity 59. In one embodiment, surface segments of a top surface of the active layer 20 may be physically exposed underneath the source cavity 51 and the drain cavity 59; and horizontal bottom surfaces of the tunneling dielectric barrier liner 81 contact segments of the top surface of the active layer 20 upon deposition of the tunneling dielectric barrier liner 81. In one embodiment, portions of the active layer 20 may be vertically recessed underneath the source cavity 51 and the drain cavity 59; and sidewalls of the tunneling dielectric barrier liner 81 contact sidewalls of recessed portions of the active layer 20 upon deposition of the tunneling dielectric barrier liner 81. In one embodiment, the tunneling dielectric barrier liner 81 may include at least one material selected from alkaline-earth metal oxides. In one embodiment, the tunneling dielectric barrier liner 81 may include a layer stack including a magnesium oxide layer and a calcium oxide layer. In one embodiment, the tunneling dielectric barrier liner 81 may include a dielectric oxide of a light Group 13 element or a transition metal oxide having a band gap larger than 3.0 eV. In one embodiment, the tunneling dielectric barrier liner 81 comprises an oxygen-free nitride of a light Group 13 element or silicon nitride.

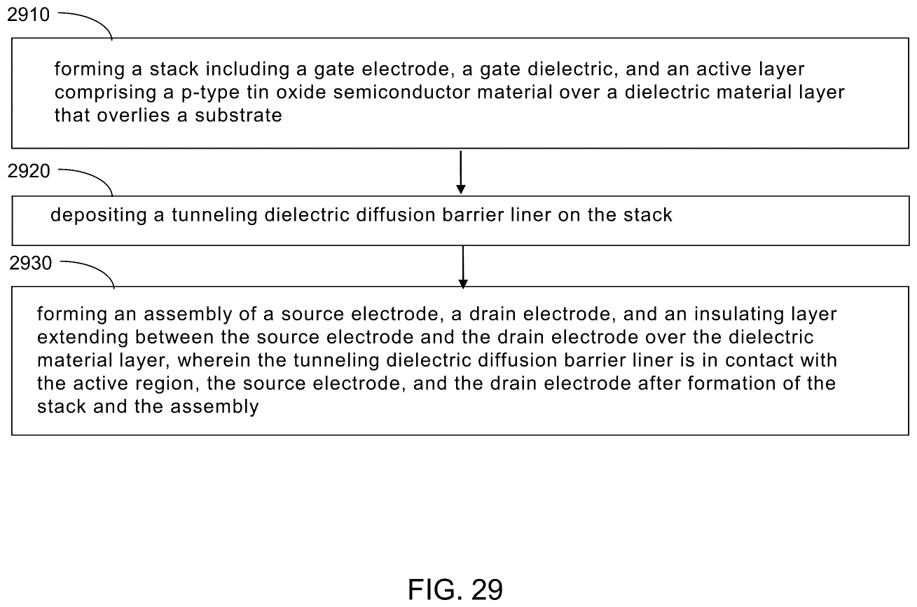

FIG. 29 is a second flowchart that illustrates the general processing steps for manufacturing the semiconductor devices of the present disclosure.

Referring to step 2910 and FIGS. 1-5C and 11A-11C, a stack (20, 10, 15) including a gate electrode 15, a gate dielectric 10, and an active layer 20 comprising a tin oxide semiconductor material may be formed over a dielectric material layer (601, 610, 620) that overlies a substrate 8.

Referring to step 2920 and FIGS. 6A-7C, a tunneling dielectric barrier liner 81 may be deposited on the stack (20, 10, 15).

Referring to step 2930 and FIGS. 7A-10C and 12A-14C, an assembly of a source electrode 80S, a drain electrode 80D, and an insulating layer 40 extending between the source electrode 80S and the drain electrode 80D may be formed over the dielectric material layer (601, 610, 620) after formation of the stack (20, 10, 15). The tunneling dielectric barrier liner 81 is in contact with the active layer 20, the source electrode 80S, and the drain electrode 80D after formation of the stack (20, 10, 15) and the assembly (80S, 40, 80D).

In one embodiment, the assembly (80S, 80D, 40) may be formed after formation the stack (20, 10, 15) by: depositing the insulating layer 40 over the active layer 20; forming a source cavity 51 and a drain cavity 59 through the insulating layer 40; and forming the source electrode 80S and the drain electrode 80D in the source cavity 51 and in the drain cavity 59, respectively. In one embodiment, the tunneling dielectric barrier liner 81 may be formed on all sidewalls of the source cavity 51 and the drain cavity 59, on physically exposed surface segments of the active layer 20, and over the insulating layer 40. In one embodiment, the assembly (80S, 80D, 40) may be formed prior to formation of the stack (20, 10, 15) by: forming the insulating layer 40 over the dielectric material layer 10; forming a source cavity 51 and a drain cavity 59 in the insulating layer 40; filling the source cavity 51 and the drain cavity 59 with at least one metallic material 84; and removing portions of the at least one metallic material 84 from outside the source cavity 51 and the drain cavity 59, wherein the source electrode 80S and the drain electrode 80D comprise portions of the at least one metallic material 84 that remains in the source cavity 51 and the drain cavity 59. In one embodiment, the tunneling dielectric barrier liner 81 may be deposited on top surfaces of the source electrode 80S and the drain electrode 80D and on a planar top surface of the insulating layer 40. In one embodiment, the tunneling dielectric barrier liner 81 may be formed by depositing a layer stack (811, 812) of at least two alkaline-earth metal oxide layers.

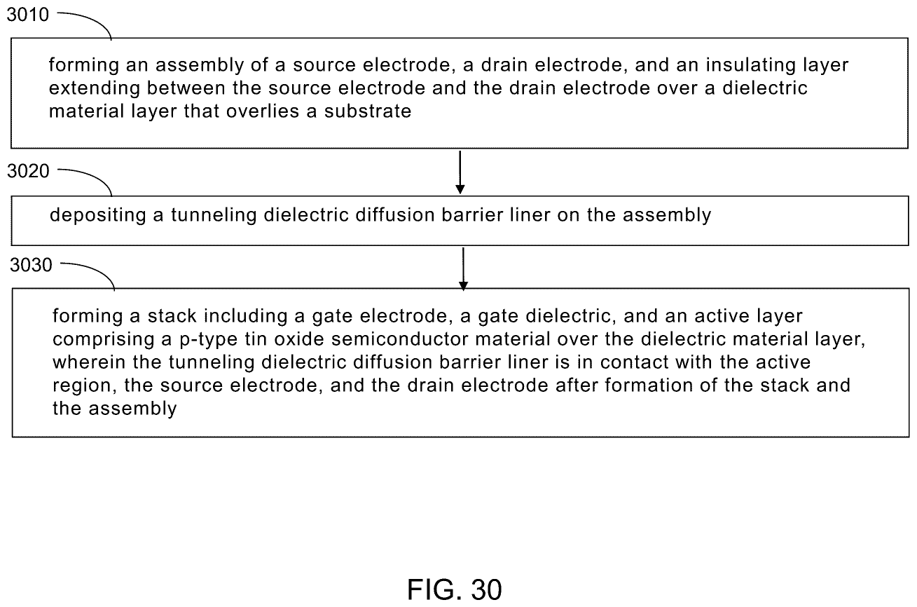

FIG. 30 is a third flowchart that illustrates the general processing steps for manufacturing the semiconductor devices of the present disclosure.

Referring to step 3010 and FIGS. 16 and 20, an assembly (80S, 40, 80D) of a source electrode 80S, a drain electrode 80D, and an insulating layer 40 extending between the source electrode 80S and the drain electrode 80D may be formed over a dielectric material layer (601, 610, 620) that overlies a substrate.

Referring to step 3020 and FIGS. 17 and 21, a tunneling dielectric barrier liner 81 may be deposited on the assembly (80S, 40, 80D).

Referring to step 3030 and FIGS. 17-20 and 21-23, a stack (20, 10, 15) including a gate electrode 15, a gate dielectric 10, and an active layer 20 comprising a tin oxide semiconductor material may be formed over the dielectric material layer (601, 610, 620). The tunneling dielectric barrier liner 81 is in contact with the active layer 20, the source electrode 80S, and the drain electrode 80D after formation of the stack (20, 10, 15) and the assembly (80S, 40, 80D).

According to an aspect of the present disclosure, the tunneling dielectric barrier liner 81 of the present disclosure protects the p-type tin oxide semiconductor material of an active layer 20 from diffusion of metallic materials from metallic electrodes (such as the source/drain electrodes 80), and provides low contact resistance by preventing formation of metal-induced gap states (MIGS). The tunneling dielectric barrier liner 81 of the present disclosure enables effective use of near stoichiometric tin monoxide as a p-type semiconductor material for thin-film transistor applications by enhancing the stability and electrical contact characteristics.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure comprising:
forming a stack including a gate electrode, a gate dielectric, and an active layer comprising a tin oxide compound semiconductor material composed primarily of tin monoxide over a dielectric material layer that overlies a substrate;
depositing a tunneling dielectric barrier liner on a surface of the active layer; and
forming a source electrode and a drain electrode on the tunneling dielectric barrier liner, wherein each of the source electrode and the drain electrode is spaced from a respective surface segment of the active layer by a respective portion of the tunneling dielectric barrier liner.

2. The method of claim 1, further comprising:
depositing an insulating layer over the stack; and
forming a source cavity and a drain cavity through the insulating layer, wherein the tunneling dielectric barrier liner is deposited in peripheral regions of the source cavity and the drain cavity.

3. The method of claim 2, wherein:
surface segments of a top surface of the active layer are physically exposed underneath the source cavity and the drain cavity; and
horizontal bottom surfaces of the tunneling dielectric barrier liner contact segments of the top surface of the active layer upon deposition of the tunneling dielectric barrier liner.

4. The method of claim 2, wherein:
portions of the active layer are vertically recessed underneath the source cavity and the drain cavity; and
sidewalls of the tunneling dielectric barrier liner contact sidewalls of recessed portions of the active layer upon deposition of the tunneling dielectric barrier liner.

5. The method of claim 1, wherein the tunneling dielectric barrier liner comprises at least one material selected from alkaline-earth metal oxides.

6. The method of claim 5, wherein the tunneling dielectric barrier liner comprises a layer stack including a magnesium oxide layer and a calcium oxide layer.

7. The method of claim 1, wherein the tunneling dielectric barrier liner comprises a dielectric oxide of a light Group 13 element or a transition metal oxide having a band gap larger than 3.0 eV.

8. The method of claim 1, wherein the tunneling dielectric barrier liner comprises an oxygen-free nitride of a light Group 13 element or silicon nitride.

9. A method of forming a semiconductor structure comprising:
forming a stack including a gate electrode, a gate dielectric, and an active layer comprising a tin oxide semiconductor material over a dielectric material layer that overlies a substrate;
forming an assembly of a source electrode, a drain electrode, and an insulating layer extending between the source electrode and the drain electrode over the dielectric material layer prior to, or after, formation of the stack; and
depositing a tunneling dielectric barrier liner on the stack or on the assembly, wherein the tunneling dielectric barrier liner is in contact with the active layer, the source electrode, and the drain electrode after formation of the stack and the assembly.

10. The method of claim 9, wherein the assembly is formed after formation the stack by:
depositing the insulating layer over the active layer;
forming a source cavity and a drain cavity through the insulating layer; and
forming the source electrode and the drain electrode in the source cavity and in the drain cavity, respectively.

11. The method of claim 10, wherein the tunneling dielectric barrier liner is formed on all sidewalls of the source cavity and the drain cavity, on physically exposed surface segments of the active layer, and over the insulating layer.

12. The method of claim 9, wherein the assembly is formed prior to formation of the stack by:
forming the insulating layer over the dielectric material layer;
forming a source cavity and a drain cavity in the insulating layer;
filling the source cavity and the drain cavity with at least one metallic material; and
removing portions of the at least one metallic material from outside the source cavity and the drain cavity, wherein the source electrode and the drain electrode comprise portions of the at least one metallic material that remains in the source cavity and the drain cavity.

13. The method of claim 12, wherein the tunneling dielectric barrier liner is deposited on top surfaces of the source electrode and the drain electrode and on a planar top surface of the insulating layer.

14. The method of claim 9, wherein the tunneling dielectric barrier liner is formed by depositing a layer stack of at least two alkaline-earth metal oxide layers.

15. A semiconductor structure comprising:
a stack overlying a dielectric material layer that is located over a substrate, wherein the stack comprise a gate electrode, a gate dielectric, and an active layer comprising a tin oxide semiconductor material;
a source electrode and a drain electrode that are spaced from each other by a portion of an insulating layer; and
at least one tunneling dielectric barrier liner located on a surface of the active layer, wherein each of the source electrode and the drain electrode is spaced from the active layer by the at least one tunneling dielectric barrier liner.

16. The semiconductor structure of claim 15, wherein:
the insulating layer overlies the stack;
each of the source electrode and the drain electrode vertically extends through the insulating layer; and
each of the source electrode and the drain electrode has a respective top surface located within a horizontal plane including a top surface of the insulating layer.

17. The semiconductor structure of claim 15, wherein:
each of the source electrode and the drain electrode overlies or underlies the insulating layer; and
the at least one tunneling dielectric barrier liner comprises a single tunneling dielectric barrier liner contacting a sidewall of the insulating layer and a sidewall of one of the source electrode and the drain electrode.

18. The semiconductor structure of claim 15, wherein the at least one tunneling dielectric barrier liner comprises a single tunneling dielectric barrier liner having a planar bottom surface that contacts a top surface of the source electrode, a top surface of the insulating layer, and a top surface of the drain electrode.

19. The semiconductor structure of claim 15, wherein the at least one tunneling dielectric barrier liner comprises at least one material selected from alkaline-earth metal oxides.

20. The semiconductor structure of claim 15, wherein the at least one tunneling dielectric barrier liner comprises a material selected from a dielectric oxide of a light Group 13 element, a transition metal oxide having a band gap larger than 3.0 eV, an oxygen-free nitride of a light Group 13 element, and silicon nitride.
